(19) United States
(12) Patent Application Publication
(10) Pub. No.: US 2026/0157032 A1
(43) Pub. Date: Jun. 4, 2026

(54) SEMICONDUCTOR DEVICE, DISPLAY DEVICE, AND PHOTOELECTRIC CONVERSION DEVICE

(71) Applicant: CANON KABUSHIKI KAISHA, Tokyo (JP)

(72) Inventors: TETSUO TAKAHASHI, Kanagawa (JP); KOJI ISHIZUYA, Kanagawa (JP); EISUKE GOMMORI, Kanagawa (JP); TAKAYUKI ITO, Kanagawa (JP); YOJIRO MATSUDA, Kanagawa (JP)

(21) Appl. No.: 19/394,379

(22) Filed: Nov. 19, 2025

(30) Foreign Application Priority Data
Nov. 29, 2024 (JP) 2024-208062

(51) Int. Cl. H10K 50/84; H10K 50/19

(52) U.S. Cl. CPC H10K 50/84; H10K 50/19

(57) ABSTRACT

One aspect relates to a semiconductor device including a lower electrode, an insulating layer, an organic layer, and an upper electrode disposed in that order. The organic layer has an electric-charge generating layer between two light-emitting layers. In a cross-section, an upper surface of the insulating layer has a groove including a bottom portion, a first steep slope portion and a first gentle slope portion disposed between the bottom portion and the first steep slope portion. A height of the first steep slope portion is less than a length from an upper surface of the lower electrode to a lower surface of the electric-charge generating layer in a region in which the lower electrode is in contact with the organic layer.

### BACKGROUND

### Field of the Technology

The present disclosure relates to a semiconductor device, a display device, a photoelectric conversion device, an electronic device, an eyewear, an image forming device, and a movable body.

### Description of the Related Art

Semiconductor devices that include light-emitting elements and photoelectric conversion elements have been proposed as devices in which organic layers are used. A light-emitting element may include an upper electrode, a lower electrode, and an organic layer disposed between the upper electrode and the lower electrode, and emits light by exciting an organic compound included in the organic layer. In recent years, devices that include organic light-emitting elements have attracted attention.

In some semiconductor devices that include organic light-emitting elements, a plurality of the light-emitting elements have a common organic layer. In this configuration, leakage of electric current through the organic layer between adjacent light-emitting elements tends to occur. Leakage current between light-emitting elements causes unintended light emission of the light-emitting elements. For example, when a semiconductor device is used in a display device, unintended light emission of light-emitting elements narrows the color gamut, which indicates the expression performance of the display device. Leakage current causes unintended light emission also in a single light-emitting element when a range of part of a continuous organic layer is to be caused to emit light.

Japanese Patent Laid-Open No. 2014-123527 discusses a light-emitting device that includes a tandem element in which a plurality of light emitting units are stacked as organic layers. Although the tandem element is advantageous for improving light-emission efficiency, the tandem element tends to cause leakage current between adjacent light-emitting elements through an electric-charge generating layer having high electrical conductivity. Japanese Patent Laid-Open No. 2014-123527 discusses that, to suppress leakage current between light-emitting elements, a recess is provided on a partition wall located between respective lower electrodes.

In each of the light-emitting elements discussed in Japanese Patent Laid-Open No. 2014-123527, a film thickness between an upper electrode and a lower electrode tends to be thin since the depth of the recess is large, and leakage current between the upper electrode and the electric-charge generating layer or between the electric-charge generating layer and the lower electrode more readily occurs. This may cause light emission not to occur even when a signal for light emission is input to the light-emitting elements and, as a result, may decrease light-emission efficiency and/or gradation controllability.

### SUMMARY

An aspect of the present disclosure provides a technology that is advantageous for suppressing leakage current between light-emitting elements and leakage current between an upper electrode and a lower electrode.

An aspect of the present disclosure provides a semiconductor device that includes a lower electrode disposed over an element substrate; an insulating layer disposed over the element substrate and covering an end of the lower electrode; an organic layer disposed over the lower electrode and the insulating layer; and an upper electrode disposed over the lower electrode and the insulating layer, the organic layer being interposed between the upper electrode and each of the lower electrode and the insulating layer. The organic layer includes a first light-emitting layer, a second light-emitting layer, and an electric-charge generating layer disposed between the first light-emitting layer and the second light-emitting layer. In a cross-section passing through the lower electrode, the insulating layer, and the organic layer, an upper surface of the insulating layer has a groove. The groove includes a bottom portion, a first steep slope portion, and a first gentle slope portion. The first steep slope portion is inclined at an angle greater than 50 degrees with respect to a parallel surface parallel to a lower surface of the lower electrode. The first gentle slope portion is disposed between the bottom portion and the first steep slope portion and is inclined at an angle less than or equal to 50 degrees with respect to the parallel surface. A length of the first steep slope portion in a first direction perpendicular to the parallel surface is less than a length from an upper surface of the lower electrode to a lower surface of the electric-charge generating layer in the first direction in a first region in which the lower electrode is in contact with the organic layer.

Another aspect of the present disclosure provides a semiconductor device that includes a lower electrode disposed over an element substrate; an insulating layer disposed over the element substrate and covering an end of the lower electrode; an organic layer disposed over the lower electrode and the insulating layer; and an upper electrode disposed over the lower electrode and the insulating layer, the organic layer being interposed between the upper electrode and each of the lower electrode and the insulating layer. The organic layer has a first light-emitting layer, a second light-emitting layer, and an electric-charge generating layer disposed between the first light-emitting layer and the second light-emitting layer. In a cross-section passing through the lower electrode, the insulating layer, and the organic layer, an upper surface of the insulating layer has a groove. The groove includes a bottom portion and a first steep slope portion that is inclined at an angle greater than 50 degrees with respect to a parallel surface parallel to a lower surface of the lower electrode. A length of the first steep slope portion in a first direction perpendicular to the parallel surface is less than a length from an upper surface of the lower electrode to a lower surface of the electric-charge generating layer in the first direction in a first region in which the lower electrode is in contact with the organic layer. A ratio of a length of the groove in the first direction relative to a distance between upper end portions of the groove in a second direction parallel to the parallel surface is 3.6 or less.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram of a cross-section of one example of a portion of a semiconductor device according to an embodiment.

FIG. 2 is a schematic diagram of a plane of one example of a portion of a semiconductor device according to an embodiment.

FIG. 3 is a schematic diagram of a plane of one example of a portion of a display device according to an embodiment.

FIG. 4 is a schematic diagram of a cross-section of one example of a portion of a semiconductor device according to an embodiment.

FIGS. 5A and 5B are schematic diagrams of a cross-section of one example of a portion of a semiconductor device according to an embodiment.

FIG. 6 is a schematic diagram of a cross-section of one example of a portion of a semiconductor device according to an embodiment.

FIG. 7A and FIG. 7B are explanatory diagrams of vapor deposition simulation according to an embodiment.

FIG. 8 is an explanatory diagram of vapor deposition simulation according to an embodiment.

FIG. 9 is an explanatory diagram of vapor deposition simulation according to an embodiment.

FIG. 10A, FIG. 10B, FIG. 10C, and FIG. 10D are explanatory diagrams of vapor deposition simulation according to an embodiment.

FIG. 11 is a diagram of a portion of a semiconductor device according to an embodiment.

FIG. 12 is a relation diagram of chromaticity of red pixels and a ratio of a distance D between ends of insulating layers located over two adjacent lower electrodes relative to a layer thickness C of an organic layer in contact with the lower electrodes.

FIG. 13 is a schematic diagram of a cross-section of one example of a portion of a semiconductor device according to an embodiment.

FIG. 14 is a schematic sectional diagram illustrating one example of pixels of a display device according to an embodiment.

FIG. 15 is a schematic diagram illustrating one example of a display device according to an embodiment.

FIG. 16A is a schematic diagram illustrating one example of an imaging device according to an embodiment. FIG. 16B is a schematic diagram illustrating one example of an electronic device according to an embodiment.

FIG. 17A is a schematic diagram illustrating one example of a display device according to an embodiment. FIG. 17B is a schematic diagram illustrating one example of a foldable display device.

FIG. 18A is a schematic diagram illustrating one example of a wearable device according to an embodiment. FIG. 18B is a schematic diagram illustrating one example of a wearable device according to an embodiment in a form including an imaging device.

FIG. 19A is a schematic diagram of an image forming device according to an embodiment. FIG. 19B and FIG. 19C are schematic diagrams each illustrating a form in which a plurality of light-emitting portions of an exposure light source are disposed on an elongated substrate.

FIG. 20 is a schematic diagram illustrating one example of an automobile, which includes a vehicle lighting appliance and a display portion, according to an embodiment.

### DESCRIPTION OF THE EMBODIMENTS

A semiconductor device according to the present disclosure may be an organic light-emitting device in which an organic layer may have, for example, a light-emitting layer.

Hereinafter, a semiconductor device according to the present disclosure and specific embodiments of various devices including the semiconductor device will be described with reference to the accompanying drawings. In the following description and the drawings, components common among a plurality of the drawings are given common reference signs. Thus, a plurality of the drawings will be mutually referred for description of common components, and description of components having common reference signs will be omitted, as appropriate. For conciseness, descriptions of portions having similar functions, configurations, materials, effects, and the like are not repeated for each embodiment but rather are incorporated by reference.

### First Embodiment

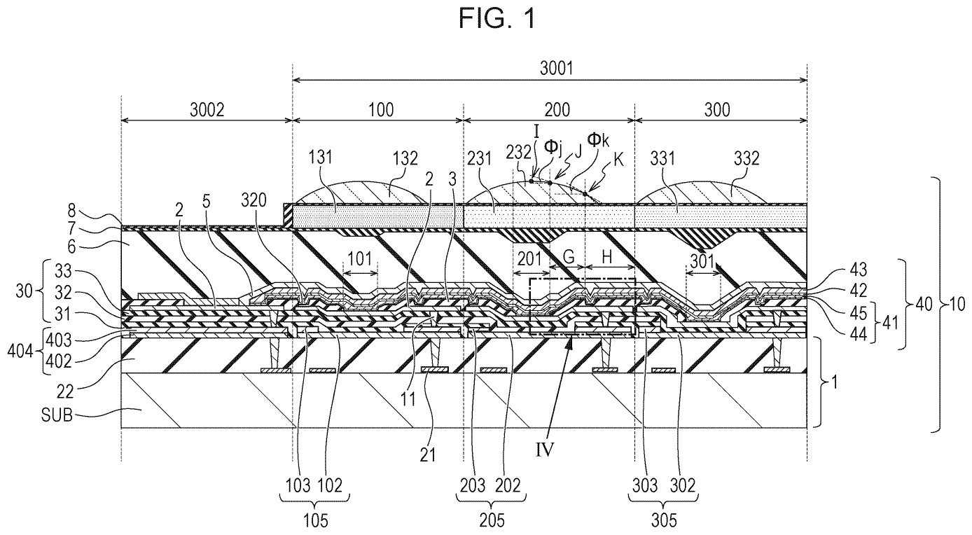

One example of a configuration of the semiconductor device according to the present embodiment will be described with reference to FIGS. 1 to 15. As an example of the semiconductor device, a light-emitting device that includes an organic light-emitting element will be described here.

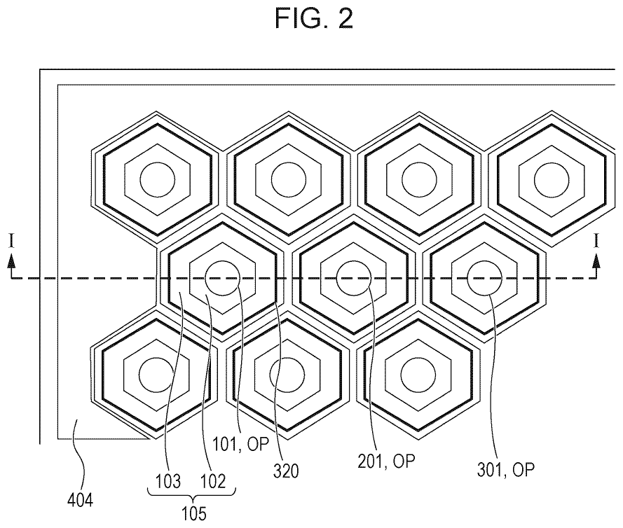

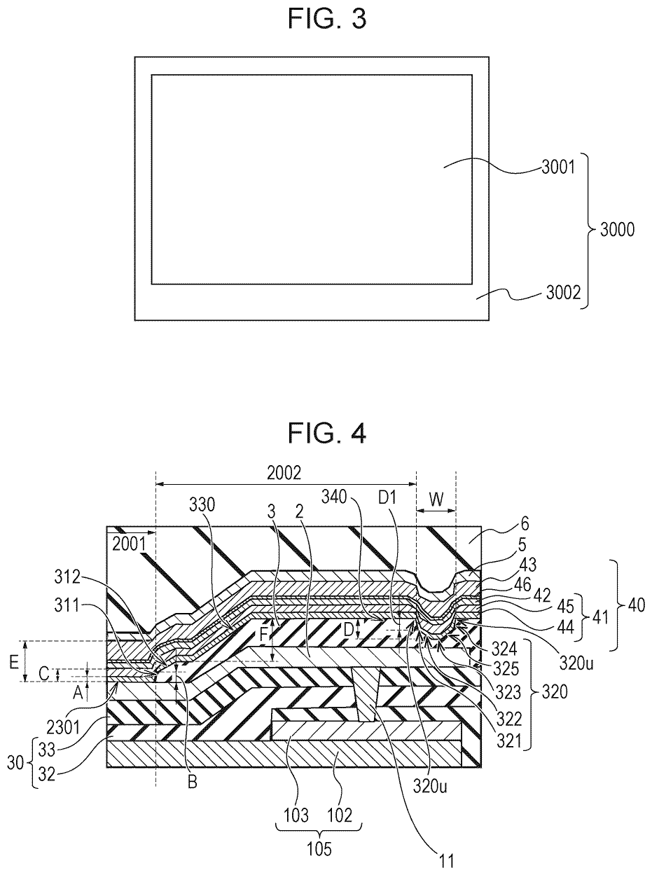

FIG. 1 is a schematic diagram of a cross-section of a portion of the light-emitting device according to the present embodiment. FIG. 2 is a schematic diagram of a plan view of a portion of the light-emitting device according to the present embodiment, with FIG. 1 being taken along the line I-I in FIG. 2. FIG. 3 is a schematic diagram of a plan view of a display device that includes the semiconductor device according to the present embodiment.

As used herein, “upper” and “lower” refer to the order of components in FIG. 1, with substrate SUB being provided as lower component. A face of a main surface of an element substrate 1 on which a lower electrode 2 and the like are disposed is referred to as the upper surface of the element substrate 1. A face of the lower electrode 2 on the element substrate 1 is referred to as the lower surface of the lower electrode 2. Therefore, for example, when a plug or the like for connection with other wires is connected to the lower surface of the lower electrode 2, a substantially flat portion of the lower surface, excluding a portion where the plug or the like is provided, is the lower surface.

The main surface of the element substrate 1 denotes the face (upper surface) on which the lower electrode 2 and the like are disposed. When the main surface (the face on which the lower electrode 2 is disposed) of the element substrate 1 has irregularities, a face parallel to the main surface of the element substrate 1 denotes a face parallel to a face (the lower surface) of the lower electrode 2 facing the element substrate 1. When the semiconductor device has a reflective layer, the surface of the element substrate 1 denotes a face on which the reflective layer is disposed, and a face parallel to the main surface of the element substrate 1 may be a face parallel to a face (the lower surface) of the reflective layer facing the element substrate 1.

In FIG. 3, a display device 3000 has a display region 3001 and a peripheral region 3002. In the display region 3001, a plurality of pixels each having a light-emitting element are two-dimensionally disposed. In the peripheral region 3002, a perpendicular-scanning circuit, a horizontal-scanning circuit, a timing generator, and the like for driving the plurality of pixels may be disposed. In addition, a terminal for external connection may be disposed in the peripheral region 3002, and a substrate that includes the perpendicular-scanning circuit, the horizontal-scanning circuit, the timing generator, and the like may be electrically connected to the display region 3001. FIG. 2 is an enlarged view of a portion of the display region 3001 in FIG. 3.

The semiconductor device according to the present embodiment includes the lower electrode 2 disposed over the element substrate 1; an insulating layer 3 disposed over the element substrate 1 to cover an end of the lower electrode 2; and an organic layer 40 disposed over the lower electrode 2 and the insulating layer 3. The semiconductor device also includes an upper electrode 5 that is disposed over the lower electrode 2 and the insulating layer 3 with the organic layer 40 interposed therebetween. The organic layer 40 has a first organic layer 41 having a first light-emitting layer 45; a second organic layer 43 having a second light-emitting layer 46; and an electric-charge generating layer 42 disposed between the first organic layer 41 having the first light-emitting layer 45 and the second organic layer 43 having the second light-emitting layer 46.

FIG. 1 illustrates a cross-section passing through the lower electrode 2, the insulating layer 3, and the organic layer 40. The upper surface of the insulating layer 3 in FIG. 1 has a groove 320.

The semiconductor device according to the present embodiment will be described in detail with reference to FIG. 1. The element substrate 1 may include a wire 21, a plug, an interlayer insulating film 22, and the like that are disposed on a substrate SUB. A reflective layer 102 and a conductive layer 103 are disposed over (i.e., overlapped with and vertically higher than the main surface of the interlayer insulating film 22 in this embodiment) the main surface of the element substrate 1. Here, the reflective layer 102 and the conductive layer 103 are referred to as a reflective member 105.

An insulating layer 31 is disposed over the reflective member 105, and an insulating layer 32 is disposed over the insulating layer 31 and the reflective member 105. In addition, the insulating layer 33 is disposed over the insulating layer 32, the insulating layer 31, and the reflective member 105. Each of or a combination of the insulating layer 31, the insulating layer 32, and the insulating layer 33 is capable of functioning as an optical adjustment layer in a light-interference structure.

Here, the insulating layer 31, the insulating layer 32, and the insulating layer 33 are collectively referred to as the insulating layer 30. The number of insulating layers functioning as optical adjustment layers may be different depending on pixels. The interference structure will be described later in detail.

A conductive layer that functions as the lower electrode 2 is disposed over the insulating layer 30 and is electrically connected to the reflective member 105. Transmittance of the lower electrode 2 is higher than reflectance thereof with respect to light that is emitted by light-emitting elements. The insulating layer 3 covers an end of the lower electrode 2 and is disposed over (over the insulating layer 30 in this embodiment) the element substrate 1. The insulating layer 3 has an opening over the lower electrode 2, the organic layer 40 is disposed over the lower electrode 2 at the opening and over the insulating layer 3, and the lower electrode is disposed over the organic layer 40.

The organic layer 40 has the first organic layer 41 that has an electric-charge transport layer 44 and the first light-emitting layer 45. The electric-charge transport layer 44 is in contact with the lower electrode 2 and the insulating layer 3. The first light-emitting layer 45 is disposed over the electric-charge transport layer 44. The organic layer 40 also has the electric-charge generating layer 42 disposed over the first organic layer 41, and the second organic layer 43 disposed over the electric-charge generating layer 42 and having the second light-emitting layer 46.

The upper electrode 5 is disposed over the organic layer 40. In the peripheral region 3002, the upper electrode 5 may be connected to a conductive layer formed by the same layer as the lower electrode 2. An insulating layer 6 may be disposed to cover the lower electrode with an insulating layer 7 disposed over the insulating layer 6. The insulating layer 6 may function as a protective layer, and the insulating layer 7 may function as a planarization layer. More specific details of the semiconductor device according to the present embodiment will be described later.

FIG. 4 is a sectional view, in which the portion IV enclosed by a dotted line in FIG. 1 is enlarged, of one example of a portion of the semiconductor device. The upper surface of the insulating layer 3 has the groove 320 in a cross-section cut in a direction perpendicular to an extending direction of the groove 320 so as to pass through the element substrate 1, the insulating layer 3, and the organic layer 40.

The groove 320 is a recessed portion of the upper surface of the insulating layer 3 and is a portion where a recess extends in a certain direction (extension direction) in plan view.

The groove 320 includes a bottom portion 323 and a first steep slope portion 321 that is inclined at an angle such that an angle formed between the first steep slope portion 321 and a parallel surface parallel to the lower surface of the lower electrode 2 is greater than 50 degrees. Here, the bottom portion 323 is a portion where an upper surface thereof is inclined at an angle of less than 10 degrees with respect to the parallel surface in a cross-section.

The film thickness of a film that is formed at a slope portion by a film forming method, for example, by vapor deposition or the like becomes thinner as the slope portion is inclined steeper with respect to the parallel surface. Therefore, the groove 320 that includes the first steep slope portion 321 makes it possible to reduce the film thickness of the highly-conductive electric-charge generating layer 42 and possible to suppress leakage current between light-emitting elements.

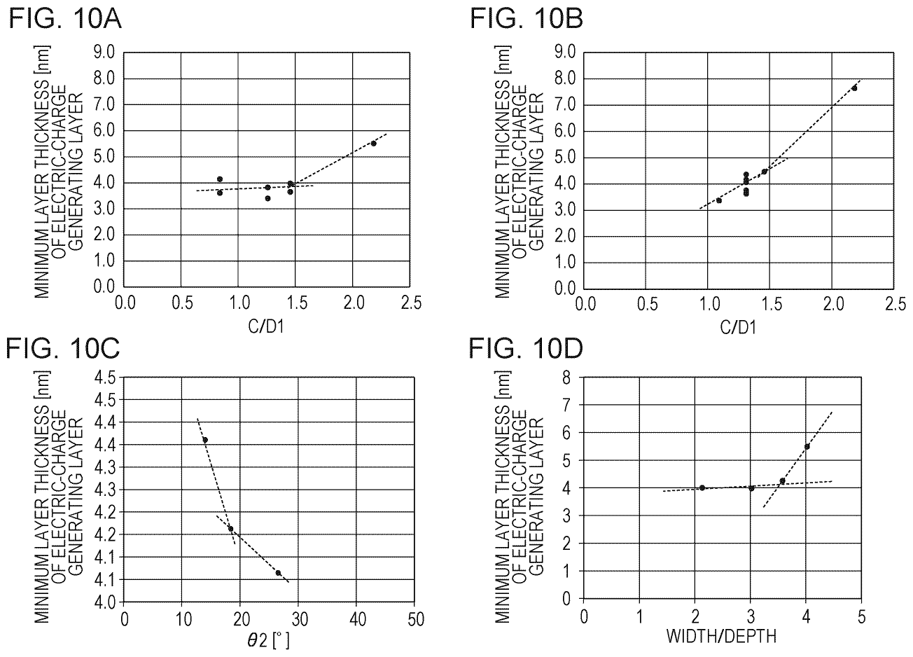

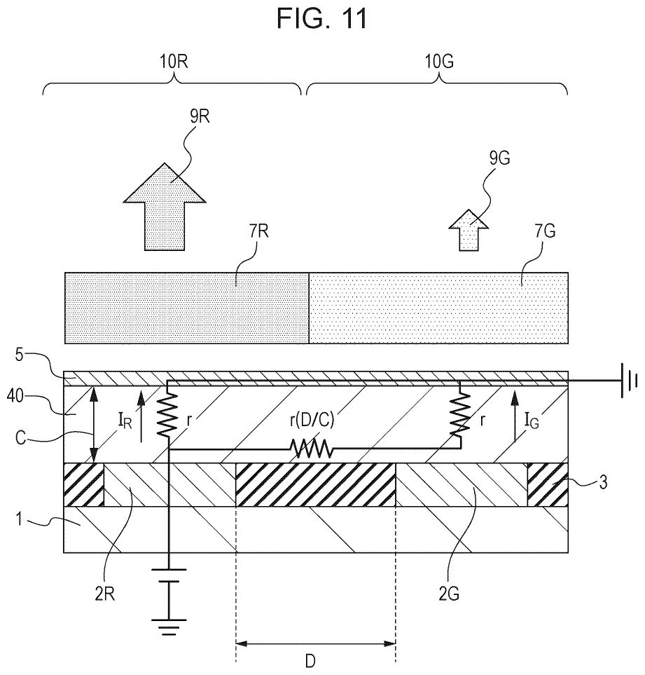

The groove 320 may include the bottom portion 323 and a first gentle slope portion 322 that is provided between the first steep slope portion 321 and the bottom portion 323 and that is inclined at an angle such that an angle formed between the first gentle slope portion 322 and the parallel surface is 50 degrees or less. The first gentle slope portion 322 makes it possible to effectively suppress the film thickness of the electric-charge generating layer, which will be described later in detail with reference to FIG. 10A and FIG. 10B. Therefore, leakage current between light-emitting elements through the electric-charge generating layer can be suppressed.

Here, an example in which a surface of the first steep slope portion 321 is inclined at an angle greater than 50 degrees with respect to the parallel surface will be presented. In FIG. 4, an example in which each of the first steep slope portion 321 and the first gentle slope portion 322 has a constant inclination angle is illustrated. The inclination angle, however, may vary in each of the slope portions. For example, when the inclination angle varies continuously from the first steep slope portion 321 toward the first gentle slope portion 322, a portion where the inclination angle is 50 degrees is a boundary between the first steep slope portion 321 and the first gentle slope portion 322.

A length D of the first steep slope portion 321 in a direction (first direction) perpendicular to a parallel surface parallel to the lower surface of the lower electrode 2 is less than a length C from the upper surface of the lower electrode 2 to the lower surface of the electric-charge generating layer 42 in the first direction in a first region 2001 in which the lower electrode 2 is in contact with the organic layer 40.

A case where the length D of the first steep slope portion 321 in the first direction is greater than the thickness (the length C from the upper surface of the lower electrode 2 to the lower surface of the electric-charge generating layer 42 in the first direction in the first region 2001) of the first organic layer 41 will be examined. In this case, a portion where the film thickness of the first organic layer 41 is reduced is formed along the first steep slope portion 321 and may cause leakage current between the lower electrode 2 and the electric-charge generating layer 42.

In contrast, in the semiconductor device according to the present embodiment, the length D of the first steep slope portion 321 is less than the thickness (corresponding to the length C) of the first organic layer in the first direction. Consequently, the first steep slope portion 321 is buried due to the thickness of the first organic layer 41 disposed over the first gentle slope portion 322. Therefore, it is possible to avoid a situation in which the first organic layer 41 becomes excessively thin at the first steep slope portion 321. It is thus possible to suppress leakage current between the lower electrode and the electric-charge generating layer.

Even in a form that includes a surface portion of the insulating layer 3 inversely tapered at 90 degrees or more, the film thickness of the electric-charge generating layer 42 is reduced due to the first steep slope portion 321. In a case where the first steep slope portion 321 is inclined at an angle of less than 90 degrees, the layer thicknesses of the first organic layer and the second organic layer at the groove are not readily reduced. Therefore, the insulating layer 3 may have a steep slope portion inclined at an angle greater than 90 degrees.

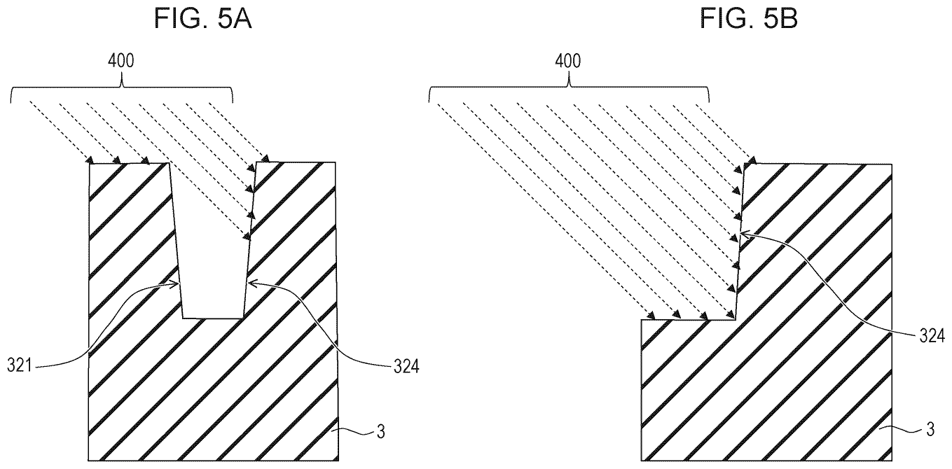

The groove is not formed as a step (only a second steep slope portion 324) that has a steep slope portion only on one side as illustrated in FIG. 5B and is formed as a groove, such as that in FIG. 5A, in which the first steep slope portion 321 and the second steep slope portion 324 face each other. Consequently, vapor deposition particles 400 intruding into the groove 320 can be limited, and the layer thickness of the electric-charge generating layer at the groove 320 can be reduced. In other words, the groove 320 may have, at a position facing the first steep slope portion 321, the second steep slope portion 324 that is inclined at an angle greater than 50 degrees with respect to the parallel surface in a cross-section.

In a method of manufacturing a semiconductor device 10 of a first embodiment, a process similar to that in Japanese Patent Laid-Open No. 2021-072282 is usable.

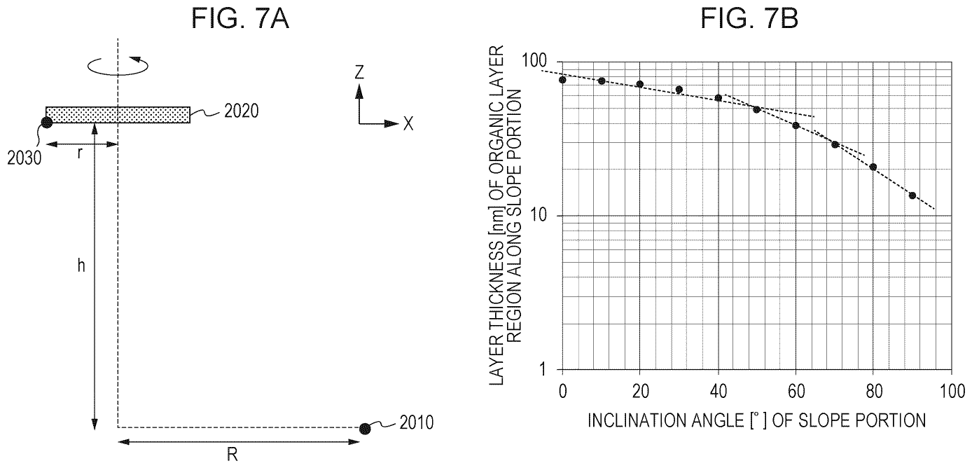

To determine inclination angles of the slope portions in the present embodiment, film formation simulation by vapor deposition was performed. FIG. 7A is an arrangement diagram of members in vapor deposition simulation. Positions of a vapor deposition source 2010, a substrate 2020, and a vapor deposition region 2030 on the substrate 2020 were set as illustrated in FIG. 7A, where distance R=200 mm, distance r=95 mm, and height h=340 mm.

In Equation (1) below, n, which represents vapor deposition distribution, is set as n=2.

$$φ = {φ}_{0} {cos}^{n} α \qquad ( 1 )$$

Here, α is an angle, φ is vapor flow density with the angle α, and φ₀ is vapor flow density when α=0. It was assumed that the substrate 2020 rotates about the center thereof. R is a distance in the horizontal direction (direction parallel to a floor of a vapor deposition device) from the center of rotation of the substrate to the center of gravity of the vapor deposition source in the horizontal direction. The distance r is a distance in the horizontal direction from the center of rotation of the substrate to the center of gravity of the vapor deposition region in the horizontal direction. The height is a distance in the perpendicular direction (direction perpendicular to the floor of the vapor deposition device) from an opening (position at which a vapor deposition material is emitted) of the vapor deposition source to a vapor deposition position in the vapor deposition region.

A case where an insulating layer includes a slope portion having an inclination angle of 0 degrees to 90 degrees in the vapor deposition region 2030 on the substrate is assumed, and the layer thickness of a region of an organic layer along the slope portion when the layer thickness of the organic layer with an inclination angle of 0 degrees is 76 nm was calculated for each inclination angle.

FIG. 7B illustrates results of the film formation simulation. From the results, it is found that the layer thickness of the region of the organic layer along the slope portion is reduced when the inclination angle is greater than 50 degrees and that the layer thickness of the region of the organic layer along the slope portion is increased when the inclination angle is less than or equal to 50 degrees. The inclination angle of the first steep slope portion 321 in the present embodiment is thus greater than 50 degrees and less than 180 degrees.

The inclination angle of the first steep slope portion 321 may be greater than or equal to 70 degrees and less than 180 degrees. Consequently, the thickness of the electric-charge generating layer can be reduced, and crosstalk current (leakage current) between light-emitting elements can be suppressed.

As illustrated in FIG. 4, the groove 320 may include, at a position facing the first steep slope portion 321, the second steep slope portion 324 that is inclined at an angle such that an angle formed between the second steep slope portion 324 and the parallel surface is greater than 50 degrees. The groove 320 may include, between the second steep slope portion 324 and the bottom portion 323, a second gentle slope portion 325 that is inclined at an angle such that an angle formed between the second gentle slope portion 325 and the parallel surface is 50 degrees or less. Consequently, the above-described effect obtained by including a gentle slope portion between a steep slope portion and a bottom portion can be obtained in more various incident directions of vapor deposition particles.

As illustrated in the sectional view in FIG. 4, a width W of the groove may be greater than twice the length C in the first direction from the upper surface of the lower electrode 2 to the lower surface of the electric-charge generating layer 42 in the first region 2001. The width W of the groove is a length between left and right ends of a recess on a flat portion 340 in a second direction parallel to the parallel surface in a cross-section that is cut in a direction perpendicular to the extending direction of the groove 320. When the groove 320 includes a slope portion, the width W of the groove is a distance in the second direction between upper end portions 320u of the groove 320 facing each other.

Consequently, the groove 320 is not readily buried at the first organic layer 41. When the recess of the groove 320 is buried at the first organic layer 41, the thickness of the electric-charge generating layer 42 formed over the recess is not readily reduced, which makes it difficult to suppress leakage current between light-emitting elements. Therefore, setting the width W of the groove 320 to the length as in the present embodiment makes it possible to effectively suppress leakage current between light-emitting elements.

As illustrated in the sectional view in FIG. 4, the bottom portion 323 of the groove 320 may be a flat portion. The flat portion is a portion that is substantially parallel to the lower surface of the lower electrode 2. Substantially parallel denotes parallel in which errors of approximately 10 degrees are allowed. Consequently, it is possible to suppress an excessive decrease in the thickness of the first organic layer 41 at the groove.

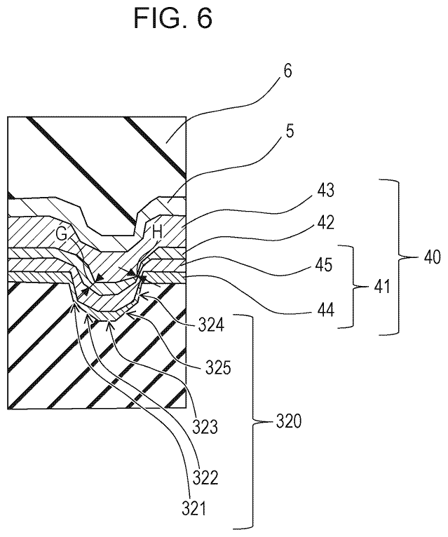

As illustrated in the sectional view in FIG. 6, in a cross-section, a thinnest layer thickness G of the electric-charge generating layer 42 formed along the first steep slope portion 321 of the groove 320 and a thinnest layer thickness H of the electric-charge generating layer 42 formed along the second steep slope portion 324 may differ from each other. This structure can be formed by using a method in which vapor deposition is performed while a wafer is rotated so as to arrange a groove at a position far from the center of rotation.

When the method, in which vapor deposition is performed while a wafer is rotated, is used to arrange the groove 320 at the center of rotation, the layer thickness G and the layer thickness H tend to be the same thickness. However, the layer thickness of either one of the layer thickness G and the layer thickness H is reduced when, in particular, the layer thickness G and the layer thickness H differ from each other. For example, when the thickness of the electric-charge generating layer is reduced at one of the two slope portions facing each other in the groove 320 and when a portion where the electric-charge generating layer 42 is formed discretely is formed, the portion is highly resistive. Therefore, even when the thickness of the electric-charge generating layer is increased at the other one of the slope portions, an effect of suppressing leakage current between light-emitting elements can be obtained considerably. In addition, since the groove 320 includes the facing slope portions due to the structure thereof, the aforementioned layer thickness relation is achieved.

A ratio of the length in the first direction from the upper surface of the lower electrode 2 to the lower surface of the electric-charge generating layer 42 in the first region 2001 relative to the length of the first steep slope portion 321 in the first direction perpendicular to the parallel surface may be less than 1.5. Results of vapor deposition simulation serving as a basis of the above are indicated below. Here, simulation was performed for an example in which an electric-charge generating layer has an electron-supplying electric-charge generating layer and an electron-receiving electric-charge generating layer.

Positions of the vapor deposition source 2010, the substrate 2020, and the vapor deposition region 2030 arranged on the substrate are set as illustrated in FIG. 7A, where R=200 mm, r=79 mm, and h=340 mm.

In Equation (1) above, with n again representing vapor deposition distribution, n is set to be equal to 2, and the substrate 2020 assumed to rotate about the center thereof and the particles migrate after landing on the substrate.

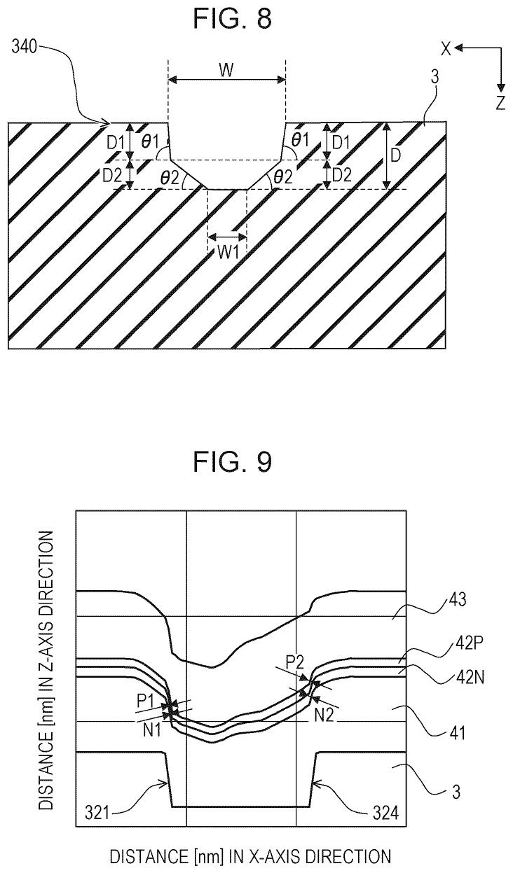

A groove such as that illustrated in FIG. 8 is provided on an insulating layer in the vapor deposition region 2030. Vapor deposition simulation was performed on grooves G1 to G7 having inclination angles and dimensions indicated in Table 1. The grooves G1 to G7 have no gentle slope portions and differ from each other in terms of groove depth or groove width. The layer thicknesses of films formed at the flat portion 340 in a perpendicular direction perpendicular to a parallel surface were set as follows. The layer thicknesses of the first organic layer 41, the electron-supplying electric-charge generating layer, the electron-receiving electric-charge generating layer, and the second organic layer 43 were set as 68.8 nm, 8.8 nm, 7.4 nm, and 60.5 nm, respectively.

TABLE 1

| | | | | | | | | | MINIMUM LAYER THICKNESS |
|---|---|---|---|---|---|---|---|---|---|
| | | | | | | | | | OF ELECTRIC-CHARGE |
| | D | D1 | θ1 | D2 | θ2 | W | W1 | | GENERATING LAYER |
| No. | [nm] | [nm] | [degree] | [nm] | [degree] | [nm] | [nm] | C/D1 | [nm] |
| G1 | 52 | 52 | 83 | 0 | — | 125 | 125 | 1.3 | 3.8 |
| G2 | 78 | 78 | 83 | 0 | — | 125 | 125 | 0.8 | 4.1 |
| G3 | 45 | 45 | 83 | 0 | — | 125 | 125 | 1.5 | 4.0 |
| G4 | 78 | 78 | 83 | 0 | — | 148 | 148 | 0.8 | 3.6 |
| G5 | 52 | 52 | 83 | 0 | — | 148 | 148 | 1.3 | 3.4 |
| G6 | 45 | 45 | 83 | 0 | — | 148 | 148 | 1.5 | 3.7 |
| G7 | 30 | 30 | 83 | 0 | — | 125 | 125 | 2.2 | 5.5 |

FIG. 9 illustrates results of vapor deposition simulation of the groove G1 and illustrates layered films in which the first organic layer 41, an electron-supplying electric-charge generating layer 42N, an electron-receiving electric-charge generating layer 42P, and the second organic layer 43 are formed in this order above the insulating layer 3. A minimum layer thickness of an electric-charge generating layer is a value that is obtained from Equation (2) below. At this time, the minimum values of the layer thicknesses of the electron-supplying electric-charge generating layer and the electron-receiving electric-charge generating layer that are on the first steep slope portion 321 side are represented by N1 and P1, respectively, and the minimum values of the layer thicknesses of the electron-supplying electric-charge generating layer and the electron-receiving electric-charge generating layer that are on the second steep slope portion 324 side are represented by N2 and P2, respectively.

$$Minimum layer thickness of electric ‐ charge generating layer = \{ ( N 1 + P 1 ) + ( N 2 + P 2 ) \} / 2 \qquad ( 2 )$$

Results of vapor deposition simulation of the grooves G1 to G7 are illustrated in FIG. 10A. C/D1 is a ratio of the layer thickness C of the first organic layer in the perpendicular direction relative to the length D1 of a steep slope portion in the perpendicular direction. It is found from this that C/D1 being less than 1.5 makes it possible to maintain small layer thicknesses of the electric-charge generating layers and that an effect of suppressing leakage current between light-emitting elements is considerable.

In addition, vapor deposition simulation was performed on grooves G8 to G16 having inclination angles and dimensions indicated in Table 2. The other calculation conditions were the same as those for the grooves G1 to G7. The grooves G8 to G16 differ from the grooves G1 to G7 and each have a gentle slope portion between a flat portion and a steep slope portion. Results of vapor deposition simulation of the grooves G8 to G16 are illustrated in FIG. 10B. It is found from this, as with FIG. 10A, that C/D1 being less than 1.5 makes it possible to maintain small layer thicknesses of the electric-charge generating layers and that the effect of suppressing leakage current between light-emitting elements is considerable.

It is found that the gradient of the graph in FIG. 10B is larger than the gradient of the graph in FIG. 10A. This means that a gentle slope portion provided between a flat portion and a steep slope portion increases the effect of reducing the layer thicknesses of the electric-charge generating layers.

TABLE 2

| | | | | | | | | | MINIMUM LAYER THICKNESS |
|---|---|---|---|---|---|---|---|---|---|
| | | | | | | | | | OF ELECTRIC-CHARGE |
| | D | D1 | θ1 | D2 | θ2 | W | W1 | | GENERATING LAYER |
| No. | [nm] | [nm] | [degree] | [nm] | [degree] | [nm] | [nm] | C/D1 | [nm] |
| G8 | 90 | 50 | 83 | 40 | 27 | 240 | 80 | 1.3 | 4.1 |
| G9 | 90 | 50 | 83 | 40 | 39 | 150 | 50 | 1.3 | 3.8 |
| G10 | 90 | 50 | 83 | 40 | 22 | 300 | 100 | 1.3 | 3.7 |
| G11 | 70 | 50 | 83 | 20 | 14 | 240 | 80 | 1.3 | 4.4 |
| G12 | 90 | 50 | 83 | 40 | 18 | 240 | 120 | 1.3 | 4.2 |
| G13 | 70 | 50 | 83 | 20 | 22 | 150 | 50 | 1.3 | 3.6 |
| G14 | 100 | 60 | 83 | 40 | 27 | 240 | 80 | 1.1 | 3.4 |
| G15 | 85 | 45 | 83 | 40 | 27 | 240 | 80 | 1.5 | 4.5 |
| G16 | 70 | 30 | 83 | 40 | 27 | 240 | 80 | 2.2 | 7.6 |

The first gentle slope portion 322 may include a portion that is inclined at an angle such that an angle formed between the portion and a parallel surface is 18 degrees or more. Results of vapor deposition simulation serving as a basis of the above are indicated below.

FIG. 10C illustrates results of vapor deposition simulation of the grooves G8, G11, and G12. The results are results of confirmation of θ2-dependence of the minimum layer thicknesses of the electric-charge generating layer by setting the length D1 and the width W of the steep slope portion of each of the grooves in the first direction to be constant and varying a length D2 of the gentle slope portion and the length (width) W1 of the flat portion in the second direction. From the results, it is found that the effect of reducing the layer thicknesses of the electric-charge generating layer, that is, the effect of suppressing leakage current between light-emitting elements increases when θ2 is 18 degrees or more.

In the semiconductor device according to the present embodiment, the ratio of the width of the groove relative to the depth of the groove may be 3.6 or less. Results of vapor deposition simulation serving as a basis of the above are indicated below.

Vapor deposition simulation was performed on the grooves G17 to G19 having inclination angles and dimensions indicated in Table 3. The grooves G17 to G19 differ from the groove G3 in terms of the width W of respective grooves and the width W1 of respective flat portions of the grooves. The other calculation conditions are the same as those for the grooves G1 to G7.

TABLE 3

| | | | | | | | | | MINIMUM LAYER THICKNESS |
|---|---|---|---|---|---|---|---|---|---|
| | | | | | | | | | OF ELECTRIC-CHARGE |
| | D | D1 | θ1 | D2 | θ2 | W | W1 | | GENERATING LAYER |
| No. | [nm] | [nm] | [degree] | [nm] | [degree] | [nm] | [nm] | W/D | [nm] |
| G17 | 45 | 45 | 83 | 0 | | 170 | 170 | 3.8 | 5.5 |
| G3 | 45 | 45 | 83 | 0 | | 125 | 125 | 2.8 | 4.0 |
| G18 | 45 | 45 | 83 | 0 | | 85 | 85 | 1.9 | 4.0 |
| G19 | 45 | 45 | 83 | 0 | | 150 | 150 | 3.3 | 4.3 |

FIG. 10D illustrates results of vapor deposition simulation of grooves G3 and G17 to G19. From the results, it is found that, when the ratio of the width W of the groove relative to the depth D of the groove is 3.6 or less, the minimum layer thickness of the electric-charge generating layer can be maintained to be small, that is, the effect of suppressing leakage current between light-emitting elements is considerable.

In the light-emitting device in FIG. 11, resistance per unit area of the organic layer 40 in a direction parallel to the lower surface of the lower electrode 2 is r(D/C). From this, when electric current that flows through a light-emitting element 10R is represented by IR and electric current that flows through a light-emitting element 10G is represented by IG, the relation of Equation (3) is established:

$$IG / IR = 1 / ( 1 + D / C ) \qquad ( 3 )$$

From the Equation (3) above, it is found that the electric current that flows through the light-emitting element 10R and the electric current that flows through the light-emitting element 10G have proportional relation with the thickness C of the organic layer 40 and the distance D as coefficients. In other words, causing only the red light-emitting element 10R to emit light also causes electric current to flow through the green light-emitting element 10G and causes the green light-emitting element 10G to emit light, and this depends on D/C.

When an emission spectrum of only the red light-emitting element 10R is represented by SR and an emission spectrum of only the green light-emitting element 10G is represented by SG in light emission caused by the same amount of electric current, an emission spectrum SR+G in consideration of leakage current between the lower electrodes 2 is expressed by Equation (4):

$$SR + G = SR + SG ( IG / IR ) \qquad ( 4 )$$

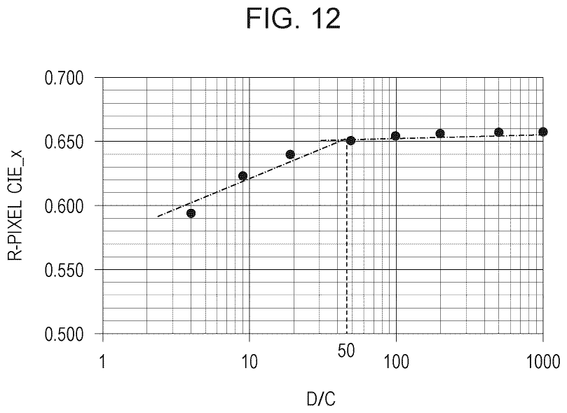

A chromaticity coordinate of the emission spectrum SR+G in a CIExy space was calculated, and a graph in which the vertical axis indicates the x-value and the horizontal axis indicates the ratio D/C is illustrated in FIG. 9. In FIG. 9, variation in the x-coordinate means that green light is also emitted although red light emission is intended. In other words, in FIG. 12, the x-coordinate being low indicates occurrence of leakage current leaking to adjacent pixels. When the ratio D/C is 50 or more, the x-value does not change substantially. In other words, even when the insulating layer 3 includes no slope portion and tends to cause leakage current between the lower electrodes 2, leakage current between the lower electrodes 2 may be not a problem when the ratio D/C is 50 or more.

In contrast, when the ratio D/C is less than 50, the x-value decreases significantly, the color purity of the red color decreases remarkably, and it is found that the color purity is affected by leakage current between the lower electrodes 2. In other words, since arrangement density of light-emitting elements is high when the ratio D/C is less than 50, leakage current between the lower electrodes 2 remarkably affects the light-emitting device. Thus, the effect of suppressing leakage current between the lower electrodes 2 is high, in particular, when the ratio D/C is less than 50.

Next, a structure in consideration with light interference of light-emitting elements will be described. An optical distance between the upper electrode 5 and the lower electrode 2 of the semiconductor device according to the present embodiment may form a constructive interference structure. The constructive interference structure can be called a resonance structure.

It is possible, by forming a plurality of layers included in an organic layer 40 so as to satisfy conditions for constructive optical interference in the light-emitting elements 10, to increase the intensity of extracted light from the light-emitting device by the optical interference. When optical conditions for increasing the intensity of extracted light in the front direction are set, light is emitted in the front direction more efficiently. In addition, it is known that the half-value width of an emission spectrum of light whose intensity is increased by optical interference is less than the half-value width of the emission spectrum before interference. In other words, color purity can be increased.

When the light-emitting element is designed for light having a wavelength λ, it is possible to achieve constructive interference by adjusting a distance do from a light-emission position in the light-emitting layer to a reflective surface of a light reflective material such that d0=iλ/4n0 (i=1, 3, 5, . . . ).

As a result, components in the front direction are increased in emission distribution of the light having the wavelength λ, and front luminance improves.

Note that n0 is a refractive index of a layer from the light-emission position to the reflective surface at the wavelength λ.

An optical distance Lr between the light-emission position and a reflective surface of a light reflection electrode is expressed by Equation (5) below, where φr [rad] represents a sum of phase shift amounts when the light having the wavelength λ is reflected by the reflective surface, and an optical distance L is the total sum of products of a refractive index nj of each layer of the organic layer and a thickness dj of each layer. In other words, L can be expressed as Σnj×dj and also can be expressed as n0×d0. Note that φ is a negative value.

$$Lr = ( 2 m - ( φ r / π ) ) \times ( λ / 4 ) \qquad ( 5 )$$

In Equation (5) above, m is an integer that is greater than or equal to zero. Note that, when φ=−π, L=λ/4 when m=0 and L=3λ/4 when m=1. Hereinafter, m=0 in Equation (5) above provides the λ/4 interference condition, and m=1 provides the 3λ/4 interference condition.

An optical distance L_{S} between the light-emission position and a reflective surface of a light extraction electrode is expressed by the Equation (6) below, where φs [rad] represents a sum of phase shift amounts when the light having the wavelength λ is reflected by an emission surface. In the following Equation (6), m′ is an integer that is greater than or equal to zero.

$$Ls = ( 2 {m}^{′} - ( φ s / π ) ) \times ( λ / 4 ) = - ( φ s / π ) \times ( λ / 4 ) \qquad ( 6 )$$

Therefore, all-layer interference length L is expressed by the Equation (7):

$$L = ( Lr + Ls ) = ( 2 m - ( φ / π ) ) \times ( λ / 4 ) \qquad ( 7 )$$

Here, φ represents a sum (φr+φs) of phase shift amounts when the light having the wavelength λ is reflected by the light reflection electrode and the light extraction electrode.

At this time, regarding actual light-emitting elements, the all-layer interference L does not necessarily coincide with the above Equation (7) strictly when viewing-angle characteristics and the like having trade-off relation with the front extraction efficiency are considered. Specifically, errors within a range from a value with which L satisfies Equation (7) to a value of ±λ/8 are tolerable. A tolerable value with which the value of L is allowed to deviate from an interference condition may be 50 nm or more and 75 nm or less.

Therefore, Equation (8) below may be satisfied in an organic light-emitting device according to the present disclosure.

The value of L may be within a range from a value that satisfies the Equation (7) to a value of #λ/16 and satisfies the following formula (8′):

$$( λ / 8 ) \times ( 4 m - ( 2 φ / π ) - 1 ) < L < ( λ / 8 ) \times ( 4 m - ( 2 φ / π ) + 1 ) \qquad ( 8 )$$

$$( λ / 16 ) \times ( 8 m - ( 4 φ / π ) - 1 ) < L < ( λ / 16 ) \times ( 8 m - ( 4 φ / π ) + 1 ) \qquad ( {8}^{′} )$$

For the light-emitting elements 10, optical interference conditions in which m=0 and m′=0, that is, in which λ/4 are in Equation (8) and Equation (8′). In this case, Equations (8) and (8′) are expressed as Equations (9) and (9′):

$$( λ / 8 ) \times ( - ( 2 φ / π ) - 1 ) < L < ( λ / 8 ) \times ( - ( 2 φ / π ) + 1 ) \qquad ( 9 )$$

$$( λ / 16 ) \times ( - ( 4 φ / π ) - 1 ) < L < ( λ / 16 ) \times ( - ( 4 φ / π ) + 1 ) \qquad ( {9}^{′} )$$

When m=0 and m′=0 in Equations (8) and (8′), the organic layer 40 has a thinnest film thickness in the constructive interference structure. Consequently, the driving voltage of the light-emitting elements 10 is reduced, and it becomes possible to emit higher-luminance light within the range of the upper limit of power source voltage. When the thickness of the organic layer 40 is reduced, leakage current between the upper electrode 5 and the lower electrode 2 more readily occurs. Therefore, it is not possible to thoughtlessly reduce the thickness of the organic layer 40 by utilizing the slope of the insulating layer 3. Therefore, by satisfying the requirements described in the present embodiment, it is possible to suppress leakage current between the lower electrodes 2 sufficiently while suppressing leakage current between the upper electrode 5 and the lower electrode 2.

Here, the light-emission wavelength λ may be a light-emission wavelength of a maximum peak of an emission spectrum emitted by a light-emitting layer. The maximum peak may have a wavelength of a minimum peak since a minimum peak in the light-emission spectrum is generally maximum light-emission in light emission of an organic compound.

The thickness of a portion of the organic layer 40, the portion being in contact with the lower electrode 2, in a direction perpendicular to the lower surface of the lower electrode 2 is less than 200 nm. Consequently, the driving voltage of the semiconductor device is reduced. In addition, the effect of the present embodiment, which makes it possible to suppress leakage current between the lower electrodes 2 while suppressing leakage current between the upper electrode 5 and the lower electrode 2, is increased.

A form of the present embodiment will be further described with FIG. 4.

The organic layer 40 has the first organic layer 41, the electric-charge generating layer 42, and the second organic layer 43. The first organic layer 41 has the electric-charge transport layer 44 and the first light-emitting layer 45. A boundary between the electric-charge generating layer 42 and the first organic layer 41 is the lower surface of the electric-charge generating layer 42. The second organic layer 43 has the second light-emitting layer 46. Each of the first organic layer 41 and the second organic layer 43 may have an electric-charge injection layer, an electric-charge block layer, and the like in addition to the aforementioned layers. The second organic layer may have an electric-charge transport layer.

In the present embodiment, the upper surface of the lower electrode 2 includes a contact portion 2301 in contact with the organic layer 40. The contact portion 2301 is uniformly flat in an example illustrated in FIG. 4 but may include a portion that is not flat with a portion of the lower electrode 2 being removed along a side surface of the insulating layer 3. The flat portion is a portion that is substantially parallel to the lower surface (the main surface of the substrate) of the lower electrode 2 and is a portion having an inclination angle of 0 degrees. The insulating layer 3 includes a third steep slope portion 311 in a second region 2002 between the first region 2001 and the groove 320, the third steep slope portion 311 being inclined at an angle greater than 50 degrees with respect to the lower surface of the lower electrode 2. The insulating layer 3 includes a gentle slope portion 312 between the third steep slope portion 311 and the fourth gentle slope portion 330.

In the present embodiment, a length B of the third steep slope portion 311 in the first direction is larger than a length A (the thickness of the electric-charge transport layer 44) in the first direction from the lower electrode 2 to the first light-emitting layer 45 in the first region 2001. Consequently, the thickness of the electric-charge transport layer 44 is reduced along the third steep slope portion 311, and it is therefore possible to suppress transport of electric charge to the groove 320 side of the third steep slope portion 311 in FIG. 4.

When the thickness of the electric-charge transport layer 44 is larger than the length B of the third steep slope portion 311 in the first direction, the third steep slope portion 311 may be buried in the electric-charge transport layer 44, and the thickness of the electric-charge transport layer 44 over the third steep slope portion 311 may be not sufficiently reduced. In this case, electric charge tends to be transported toward the groove 320 as viewed from the third steep slope portion 311 in FIG. 4 since the electric-charge transporting property of the electric-charge transport layer 44 is high.

In contrast, in the semiconductor device according to the present embodiment, the length B of the third steep slope portion 311 in the first direction is larger than the thickness of the electric-charge transport layer 44 in the first region 2001. Therefore, the layer thickness of the electric-charge transport layer 44 is small at a portion thereof in contact with the third steep slope portion 311, and leakage current between light-emitting elements can be suppressed.

In addition, in the present embodiment, the length B of the third steep slope portion 311 in the first direction from the lower electrode 2 is less than the length C (the thickness of the first organic layer 41) in the first direction from the lower electrode 2 to the electric-charge generating layer 42 in the first region 2001. Consequently, the third steep slope portion 311 is buried in the first organic layer 41, and it is possible to suppress an excessive decrease along the third steep slope portion 311 in the thickness of the first organic layer 41. Leakage current flowing between the lower electrode 2 and the electric-charge generating layer 42 causes a decrease in light-emission efficiency. However, the semiconductor device according to the present embodiment can suppress a decrease in light-emission efficiency since the semiconductor device can suppress leakage current between the lower electrode 2 and the electric-charge generating layer 42.

In the present embodiment, the insulating layer 3 includes the groove 320 at a position farther than the third steep slope portion 311 from a position (the first region 2001) at which the lower electrode 2 is in contact with the organic layer 40. The length D (the depth of the groove) of the groove 320 in the second direction perpendicular to a place parallel to the lower surface of the lower electrode 2 is larger than the length B of the third steep slope portion 311 in the first direction. Consequently, the thickness of the electric-charge generating layer 42 is reduced at the groove 320, and it is therefore possible to suppress generation and transport of electric charge in an adjacent pixel direction as viewed from the groove 320.

In this case, the thickness of the first organic layer 41 is also reduced at the groove 320. However, since the thickness of the electric-charge transport layer is reduced at the third steep slope portion 311, the amount of electric charge that reaches the groove 320 from the lower electrode 2 is reduced. Therefore, leakage current between the lower electrode 2 and the electric-charge generating layer 42 at the groove 320 is suppressed.

In the present embodiment, the length D of the groove 320 in the second direction is less than a length E (the thickness of the organic layer 40) of the organic layer 40 in the first direction in the first region 2001. Consequently, the groove 320 is buried in the second organic layer 43, and the thickness of the second organic layer 43 is not excessively reduced along the groove 320. Therefore, it is possible to suppress leakage current between the electric-charge generating layer 42 and the upper electrode 5.

The length D of the groove 320 in the second direction is larger than the length C in the first direction from the lower electrode 2 to the electric-charge generating layer 42 in the first region 2001. Consequently, the thickness of the electric-charge generating layer 42 is reduced at the groove 320.

The distance between a light emission region 101 and a light emission region 201 of a light-emitting element is 10 μm or less and may be 5 μm or less. In such a high-definition pixel arrangement, crosstalk current between organic EL elements tends to be large, and thus, the effect of the present embodiment tends to increase.

As illustrated in FIG. 4, the insulating layer includes a fourth gentle slope portion 330 between the groove 320 and the third steep slope portion 311, and a length F of the fourth gentle slope portion in the first direction is larger than the length B in the first direction from the lower electrode 2 to the electric-charge generating layer 42 in the first region 2001. Consequently, the electric-charge transport layer 44 and the electric-charge generating layer 42 can extend to be thin by a long distance, to an extent with which the first organic layer 41 and second organic layer 43 do not become excessively thin, compared with those at a location where the surface of the insulating layer 3 is flat. Therefore, it is possible to suppress leakage current between adjacent light-emitting elements. Here, a gentle slope portion is a surface portion of the insulating layer 3, the surface portion being inclined at an angle such that an inclination angle of a surface thereof is within a range from 0 degrees to 50 degrees with respect to a parallel surface parallel to the lower surface of the lower electrode 2.

The third steep slope portion 311 is disposed at an end portion of the insulating layer 3. By the end portion of the insulating layer 3 also serving as the third steep slope portion 311, it is possible to achieve space saving, which is advantageous for making pixels minute. In addition, light emission over the insulating layer 3 causes a decrease in color purity since light having wavelength different from a desired wavelength is emitted since the length in the first direction between the reflective layer 102 and the light-emitting layer is not a length suitable for optical interference. By the end portion of the insulating layer 3 also serving as the third steep slope portion 311, it is possible to dispose the third steep slope portion 311 at a position close to the first region 2001. As the third steep slope portion 311 disposed closer to the first region 2001, it becomes more difficult for electric charge to be transported over the insulating layer 3 through the electric-charge transport layer 44. Therefore, emission of light having a wavelength different from a desired wavelength over the insulating layer 3 can be suppressed.

In the sectional view in FIG. 1, a length G of the groove 320 to a position closest to the contact portion 2301 (corresponding to the first region 2001) in the second direction parallel to the lower surface of the lower electrode 2 is less than a length H of the groove 320 from the position closest to the contact portion 2301 to an intermediate position between adjacent light-emitting elements. Consequently, the distance from the contact portion 2301 to the groove 320 is reduced. Therefore, a range in which light emission over the insulating layer 3 can occur is reduced, and a decrease in color purity can be suppressed. Here, the intermediate position between adjacent pixels means a midpoint between centers of gravity of the lower electrodes 2 of adjacent light-emitting elements in the second direction parallel to the lower surface of the lower electrode 2.

The third steep slope portion 311 and the groove 320 each overlap the lower electrode 2 in plan view of a plane that is parallel to the lower surface of the lower electrode 2. Consequently, when an electric field generated by a potential difference between the lower electrode 2 and the upper electrode 5 is applied to the organic layer 40 whose thickness is reduced by the groove 320, recombination of electric charge that moves toward light-emitting elements adjacent to each other through the organic layer 40 is accelerated. Therefore, it is possible to reduce electric charge that moves between adjacent light-emitting elements and possible to suppress leakage current between adjacent light-emitting elements.

When viewed in the sectional view in FIG. 1, the first region 2001 and a vertex of a microlens 232 overlap each other, in plan view. In addition, an inclination angle Φk is greater than an inclination angle Φj. Here, the inclination angle Φj denotes an inclination angle with respect to a parallel surface parallel to the lower surface of the lower electrode 2 at a position J on a surface of the microlens directly above an end portion of the contact portion 2301. In addition, the inclination angle Φk denotes an inclination angle with respect to the parallel surface at a position K on the surface of the microlens directly above a position closest to the contact portion 2301 of the groove 320. Reasons for the above will be described below.

When guided light in a direction parallel to the parallel surface is scattered at the third steep slope portion 311 and/or the groove 320, optical interference is not properly set, and light having a wavelength different from a desired wavelength is extracted in the upward direction and may deteriorate color purity. However, due to the presence of an inclination of the surface of the microlens, the light is refracted and is not readily extracted in the upward direction. In this case, a larger effect is exerted as the inclination angle increases.

In the present embodiment, since the length of the groove 320 in the first direction is larger than the length of the third steep slope portion 311 in the first direction, the amount of scattered light at the groove 320 is increased. Thus, by increasing the inclination angle Φk to be larger than the inclination angle Φj, it is possible to further suppress extraction of scattered light in the upward direction.

As illustrated in FIG. 4, the lower end (the bottom portion) of the groove 320 is present at a position (a position far from the substrate in the first direction) higher than the upper end of the third steep slope portion 311. Consequently, mixture of colors is suppressed and color purity is improved, for the following reasons.

The light that is emitted at the first light-emitting layer 45 and the second light-emitting layer 46 intrudes into the insulating layer 3 through the third steep slope portion 311 as an entrance and is guided to propagate through the insulating layer 3 in the second direction. The groove 320 present in the insulating layer 3 can reduce the passage for the guided light. Therefore, the guided light does not readily reach an adjacent light-emitting element, and light that is extracted through a color filter of an adjacent pixel can be limited. In addition, due to the groove 320 being present above (far from the substrate in the first direction) the third steep slope portion 311, upper light, which is readily involved in mixture of colors, can be blocked, and a large effect is exerted.

The detailed structure of the semiconductor device according to the present embodiment will be described with FIG. 1. The element substrate 1 may include the substrate SUB and a switching element (not illustrated), such as a transistor, a wire 11, and the interlayer insulating film 22 that are disposed on the substrate SUB. The substrate SUB is made of a material capable of supporting the lower electrode 2, the organic layer 40, and the upper electrode 5. As the material, glass, plastic, silicon, or the like is suitable. A semiconductor substrate can be used to achieve high-speed driving and highly-dense arrangement of pixels.

From the point of view of light-emission efficiency, the lower electrode 2 of a first organic EL element 100 is made of a material having light permeability. Specifically, thin films of transparent conductive oxides, such as ITO and IZO, metals, such as Al, Ag, and Pt, and alloys are usable. When a second organic EL element 200 and a third organic EL element 300 are formed, respective lower electrodes 2 thereof are electrically separated from each other. In addition, for optimization of optical interference, the film thicknesses of the respective lower electrodes 2 of the first organic EL element 100, the second organic EL element 200, and the third organic EL element 300 may differ from each other.

The organic layer 40 is disposed over the lower electrode 2 of the first organic EL element 100. The organic layer 40 is a layer that includes at least a light-emitting layer and may be constituted by a plurality of layers.

The organic layer 40 emits light from the light-emitting layer as a result of a hole injected from an anode and an electron injected from a cathode recombining with each other in the light-emitting layer. The light-emitting layer may be constituted by a single layer or a plurality of layers. A red light emitting material, a green light emitting material, and a blue light emitting material can be each included in a respective one of the light-emitting layers, and it is also possible to obtain white light by mixing emission colors. Light emitting materials, such as a blue light emitting material and a yellow light emitting material, in complementary-color relation may be included in one of the light-emitting layers.

The organic layer 40 may include a hole transport layer, a light-emitting layer, and an electron transport layer. As materials of the organic layer 40, materials that are suitable from the point of view of each of light-emission efficiency, drive lifetime, optical interference, and the like can be selected. The hole transport layer may function as an electron block layer or a hole injection layer and may have a layered structure including a hole injection layer, a hole transport layer, an electron block layer, and the like. The light-emitting layer may have a layered structure of light-emitting layers that emit light of different colors and may be a mixture layer in which light emitting dopants that emit light of different colors are mixed together. The electron transport layer may function as a hole block layer or an electron injection layer and may have a layered structure including an electron injection layer, an electron transport layer, and a hole block layer.

A region between the light-emitting layer and one of the upper electrode 5 and the lower electrode 2 serving as an anode is a hole transport layer, and a region between the light-emitting layer and the other one serving as a cathode is an electron transport layer. The hole transport layer and the electron transport layer are collectively referred to as the electric-charge transport layer.

The lower electrode 2 is in contact with the hole transport layer. When the mobility of electric charge is higher in the hole transport layer than in the electron transport layer, the effect of the present embodiment can be obtained more considerably since leakage current between the lower electrodes 2 more readily flows.

The organic layer 40 may be a tandem type layer constituted by the electric-charge generating layer 42, the first organic layer 41 below the electric-charge generating layer, and the second organic layer 43 over the electric-charge generating layer. The first organic layer and the second organic layer each have a light-emitting layer. When there are a plurality of electric-charge generating layers, an organic layer below the lowermost electric-charge generating layer is the first organic layer.

An electric-charge transport layer, such as a hole transport layer or an electron transport layer, may be formed between an electric-charge generating layer and a light-emitting layer. An electric-charge generating layer is a layer that includes an electron-supplying material and an electron-receiving material and that generates electric charge. An electron-supplying material and an electron-receiving material are, respectively, a material that supplies electrons and a material that receives electrons. Consequently, positive electric charge and negative electric charge are generated in the electric-charge generating layer, and it is therefore possible to supply positive or negative electric charge to layers over the electric-charge generating layer and to layers below the electric-charge generating layer.

The electron-supplying material may be, for example, an alkali metal, such as lithium or cesium.

The electron-supplying material also may be, for example, lithium fluoride, a lithium complex, cesium carbonate, or a cesium complex. In this case, the electron-supplying material may express electron-supplying characteristics by being included together with a reducible material, such as aluminum, magnesium, or calcium.

The electron-supplying material may be a hole-transporting material. As the hole transporting material, a triarylamine derivative, a phenylenediamine derivative, a triazole derivative, an oxadiazole derivative, an imidazole derivative, a pyrazoline derivative, a pyrazolone derivative, an oxazole derivative, and a fluorenone derivative are usable. A hydrazone derivative, a stilbene derivative, a phthalocyanine derivative, a porphyrin derivative, and organic compounds, such as poly(vinylcarbazole), poly(silylene), poly(thiophene), and other conductive polymers are also usable.

The electron-supplying material may be included in an electron-transporting material. As the electron-transporting material, an oxadiazole derivative, an oxazole derivative, a thiazole derivative, a thiadiazole derivative, and a pyrazine derivative are usable. Organic compounds such as a triazole derivative, a triazine derivative, a perylene derivative, a quinoline derivative, a quinoxaline derivative, a fluorenone derivative, an anthrone derivative, a phenanthroline derivative, and organometallic complexes, are also usable.

The material of the electron-receiving material is, for example, an inorganic substance, including transition metal oxides such as molybdenum oxides, or an organic substance, such as a hexaazatriphenylene derivative or [dipyrazino[2,3-f:2′,3′-h]quinoxaline-2,3,6,7,10,11-hexacarbonitrile]. The electric-charge generating layer may be a layer that includes a mixture of an electron-receiving material and an electron-supplying material and may be a layer in which a layer that includes an electron-supplying material and a layer that includes an electron-receiving material are layered.

The organic layer 40 may be formed by a method described below.

For an organic layer constituting a light-emitting element according to the present embodiment, a dry process, such as a vacuum evaporation method, an ionized evaporation method, sputtering, and plasma, is usable. Instead of the dry process, a wet process in which a material is dissolved in a suitable solvent and a layer is formed by a publicly known coating method (for example, spin coating, dipping, a casting method, a LB method, an inkjet method, and the like) is usable.

Here, when a layer is formed by a vacuum evaporation method, a solution coating method, or the like, crystallization and the like are unlikely to occur in the layer, and the layer has excellent temporal stability. When a film is formed by a coating method, a material may be combined with a suitable binder resin to form a film.

The aforementioned binder resin is, for example, a polyvinyl carbazole resin, a polycarbonate resin, a polyester resin, an ABS resin, an acrylic resin, a polyimide resin, a phenolic resin, an epoxy resin, a silicon resin, a urea resin, or the like. The aforementioned resins are examples, and the binder resin is not limited to these resins.

One of these binder resins may be individually used as a homopolymer or a copolymer, and two or more of these binder resins may be mixed together and used. Further, publicly known additives such as a plasticizer, an antioxidant, and an ultraviolet absorber may be used in addition, as necessary.

The organic layer 40 is disposed between the upper electrode 5 and each of the lower electrode 2 and the insulating layer 3. The organic layer 40 may be continuously formed on the upper surface of the element substrate 1 and may be shared among a plurality of organic EL elements. In other words, the single organic layer 40 may be shared among a plurality of organic EL elements. The organic layer 40 may be integrally formed in the entirety of a display region in which an image is displayed in a light-emitting device.

When the second organic EL element 200 and the third organic EL element 300 are formed, the organic layer 40 may be disposed to extend over the lower electrode 2 of the first organic EL element, the lower electrode 2 of the second organic EL element, and the lower electrode 2 of the third organic EL element. All or part of the organic layer 40 of the first organic EL element, the second organic EL element, and the third organic EL element may be patterned for each element. The organic layer 40 may be formed in an outer peripheral region present at the outer periphery of a display region 1000.

The upper electrode 5 is disposed over the organic layer 40 of the first organic EL element and has translucency. The upper electrode 5 may be made of a semi-transparent material that has characteristics (that is, semi-transparent reflectivity) with which part of light that has reached a surface of the upper electrode 5 is transmitted while the other part of the light is reflected. The material constituting the upper electrode 5 is constituted by, for example, a transparent conductive oxide, such as ITO or IZO, a simple metal, such as aluminum, silver, or gold, an alkali metal, such as lithium or cesium, an alkaline earth metal, such as magnesium, calcium, or barium, or a semi-transparent material including an alloy material including these metal materials. The semi-transparent material is an alloy that contains, in particular, magnesium or silver as a main component.

As long as the upper electrode 5 has a transmittance, the upper electrode 5 may have a layered structure of the aforementioned materials. When the second organic EL element 200 and the third organic EL element 300 are further formed, the upper electrode 5 may be disposed over the organic layer 40 of the first organic EL element, the organic layer 40 of the second organic EL element, and the organic layer 40 of the third organic EL element. As with the organic layer 40, the upper electrode 5 may be formed integrally in the entirety of the display region 1000. The upper electrode 5 may be formed in an outer peripheral region present at the outer periphery of the display region 1000.

In the present embodiment, the lower electrode 2 may be an anode while the upper electrode 5 is a cathode or the lower electrode 2 may be a cathode while the upper electrode 5 is an anode.

In the semiconductor device, the insulating layer 3 may be provided at an outer peripheral portion of the lower electrode 2 of the first organic EL element 100. In other words, an opening portion is provided so that a portion of the lower electrode 2 is exposed. The insulating layer 3 is formed to accurately form the first light emission region 101 into a desired shape. When the insulating layer 3 is not provided, the first light emission region 101 is defined by the shape of the lower electrode 2. The insulating layer 3 is made of an inorganic material, such as silicon nitride (SiN), silicon oxynitride (SiON), or silicon oxide (SiO). For the formation of the insulating layer 3, a publicly known technique, such as sputtering or chemical vapor deposition (CVD), is usable. The insulating layer 3 can be formed with an organic material, such as an acrylic resin or a polyimide resin.

In the present embodiment, the reflective member 105 of the first pixel has, in at least part of a region overlapped by the first light emission region 101, the reflective layer 102 disposed over the element substrate 1. In at least part of a region overlapped by the first light emission region 101 and in which the conductive layer 103 is disposed over the reflective layer 102, the conductive layer 103 of a first layered portion 104 may have an opening to expose the reflective layer 102. The light that is emitted by the first organic EL element is transmitted through the lower electrode 2 and can be reflected by the reflective layer 102 efficiently. From the point of view of improving light-emission efficiency, the size of the opening of the conductive layer 103 is larger than or equal to the size of the first light emission region 101. The conductive layer 103 can function as an electric-corrosion suppressing layer.

The light that is reflected by the reflective layer 102 is extracted from the upper electrode 5 to the light emission side. Therefore, the semiconductor device according to the present embodiment can obtain characteristics of high light-emission efficiency. Here, the light emission side denotes a direction of the upper electrode 5 with respect to the lower electrode 2.

For example, the reflective layer 102 is made of a material selected from Ag and Al having high reflectance, and the conductive layer 103 is made of a material selected from Co, Mo, Pt, Ta, Ti, TiN, W, and the like. The reflective layer 102 and the conductive layer 103 can be made of alloys or compounds. A particularly suitable combination is the reflective layer 102 made of a material containing Al as a main component and the conductive layer 103 made of a material containing Ti or TiN as a main component. Further, the reflective layer 102 may contain Cu together with Al as a main component. The conductive layer 103 may contain TiN as a main component. A barrier metal of Ti or TiN may be provided on the element substrate side of the reflective member 105 of the first pixel.

The reflective layer 102 and the conductive layer 103 can be formed by a publicly known film formation method, such as sputtering, CVD, or atomic layer deposition (ALD). The reflective layer 102 can be formed with materials whose main components are the same material at the same time by, after forming a film of a high-reflectance material on an element substrate, patterning the film by a publicly known etching process. The conductive layer 103 also can be formed with materials whose main components are the same material at the same time by, after forming a film of a material on an element substrate, patterning the film by a publicly known etching process.

An opening portion of the conductive layer 103 provided at the reflective member 105 of the first pixel can be formed by removing the conductive layer 103 by a publicly known etching process.

In the present embodiment, the insulating layer 30 functioning as an optical interference layer is provided between the reflective member 105 of the first pixel and the lower electrode 2. The optical distance between the light-emitting layer of the first organic EL element 100 and the reflective layer 102 can be optimized by adjusting the thickness of the insulating layer 30. Therefore, light-emission efficiency can be improved by utilizing optical interference. The insulating layer 30 may be a single layer and may have a layered structure including a plurality of layers.

In the present embodiment, a plurality of organic EL elements, such as the second organic EL element 200 and the third organic EL element 300, can be provided in the display region 1000 in addition to the first organic EL element 100. As with the first organic EL element 100, each of the second organic EL element 200 and the third organic EL element 300 also has the organic layer 40 that includes at least a light-emitting layer between the lower electrode 2 and the upper electrode 5. Further, each of the second organic EL element 200 and the third organic EL element 300 also includes a reflective member 205 of the second pixel and a reflective member 305 of the third pixel on the element substrate side of the lower electrode 2.

As with the reflective member 105 of the first pixel, the reflective layer 202 is layered in the reflective member 205 of the second pixel, and the reflective member 205 has the reflective layer 202 in at least part of a region overlapped by a second light-emitting portion 230.

As with the reflective member 105 of the first pixel and the second pixel reflective member 205 of the second pixel, the reflective member 305 of the third pixel has a reflective layer 302 in at least part of a region overlapped by a third light-emission region 301.

Each of the second organic EL element 200 and the third organic EL element 300 can have an optical interference layer. The colors of the light that is emitted from respective organic EL elements can be adjusted by making the thicknesses of the optical interference layers of the first organic EL element 100, the second organic EL element 200, and the third organic EL element 300 different from each other. The insulating layer 30 can have a layered structure including a plurality of layers.

For example, when forming the insulating layer 30 of the first organic EL element 100, the second organic EL element 200, and the third organic EL element 300 so as to become smaller in this order, it is possible to provide a first optical interference layer 31, a second optical interference layer 32, and a third optical interference layer 33 over the reflective member 105 of the first pixel, provide the second optical interference layer 32 and the third optical interference layer 33 over the reflective member 205 of the second pixel, and provide the third optical interference layer 33 over the reflective member 305 of the third pixel.

The insulating layer 30 is made of a transparent material and may be made of SiO, SiN, or SiON. As a formation method, a publicly known technique, such as sputtering, CVD, or ALD, is usable.

The colors of the light that is emitted from respective organic EL elements are adjusted by making the thicknesses of the optical interference layers of the first organic EL element 100, the second organic EL element 200, and the third organic EL element 300 different from each other, as illustrated in FIG. 1. Consequently, it is possible to improve light-emission efficiency of the organic EL elements of respective colors. In the form in which the thicknesses of the optical interference layers of the organic EL elements are made different from each other, irregularities of the surface of the insulating layer 3 tend to be large, and therefore, leakage current between the lower electrode 2 and the electric-charge generating layer 42 or between the electric-charge generating layer 42 and the upper electrode 5 more readily occurs.

In addition, although not illustrated, a pixel contact region electrically insulated from the reflective member 105 and electrically connected to the lower electrode 2 may be provided. The lower electrode 2 and the pixel contact region may be electrically connected to each other. Consequently, the first organic EL element 100 can conduct electric current through the pixel contact region. In the pixel contact region, a wiring layer and the conductive layer 103 may be used.

The first organic EL element 100 can conduct electric current through the reflective member 105. The second organic EL element 200 and the third organic EL element 300 also may include the reflective member 205 and the reflective member 305, respectively.

When the insulating layer 30 functioning as the optical interference layer is provided, a plug 11 is provided at the insulating layer 30, and a conductive material is formed inside the plug so that the lower electrode 2 and a pixel contact region 115 can be electrically connected to each other. The conductive material inside the plug may be the same material as the lower electrode 2. As the conductive material provided inside the plug, a publicly known conductive material, such as W, Ti, or TiN, is usable.

The lower electrode 2 and the reflective member 105 may be in contact with each other through the plug. From the point of view of suppression of electric corrosion, a portion of the reflective member 105 in contact with the plug 11 is the conductive layer 103.

FIG. 2 is a plan view illustrating one form of the reflective member 105 of the first pixel of the present embodiment. When the reflective member 105 and the lower electrode 2 are in direct contact with each other, the conductive layer 103 and the lower electrode 2, in particular, are a combination that does not readily cause galvanic corrosion. For example, the conductive layer 103 may be made of a material that contains TiN as a main component while the lower electrode 2 is made of ITO or IZO.

The insulating layer 3 has the groove 320 in each pixel. The groove 320 can be patterned by etching the insulating layer 3. The groove 320 may be arranged so as to surround an opening OP of the insulating layer 3.

The insulating layer 6 functioning as a protective layer can be made of a material having low permeability with respect to oxygen and moisture from outside. The material is, for example, silicon nitride, silicon oxynitride, aluminum oxide, silicon oxide, titanium oxide, or the like. Silicon nitride and silicon oxynitride may be formed by, for example, CVD. The aluminum oxide, silicon oxide, and titanium oxide can be formed by ALD.

While the combination of the constituent material and the manufacturing method of the protective layer is not limited to the aforementioned example, the protective layer may be manufactured in consideration of a layer thickness thereof to be formed, the time required for the formation, and the like. The insulating layer 6 may have a single layer structure and may have a layered structure as long as the insulating layer 6 allows light transmitted through the upper electrode 5 to be transmitted through the insulating layer 6 and has sufficient moisture blocking performance.

Color filters 131, 231, and 331 are formed over the insulating layer 6. As with the color filter 131 and the color filter 231 illustrated in FIG. 1, the color filters may be in contact with each other with no gap therebetween. A color filter may be disposed so as to be stacked on another color filter of a different color.

The insulating layer 7 functioning as a planarization layer may be disposed below the color filters, and an insulating layer 8 functioning as a planarization layer may be disposed over the color filters.

Microlenses 132, 232, and 332 may be disposed over the insulating layer 8.

### Second Embodiment

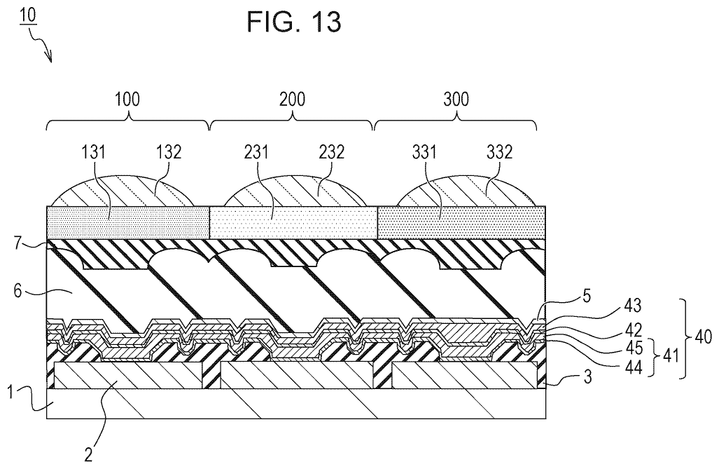

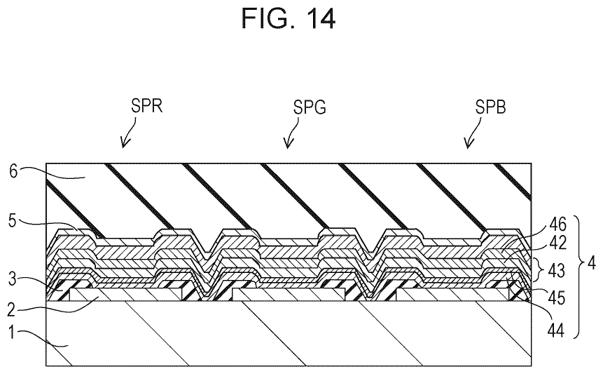

A semiconductor device according to a second embodiment in FIG. 13 is a semiconductor device similar to the semiconductor device according to the first embodiment except for a feature in which the lower electrode 2 is disposed in contact with the element substrate 1 and in which the insulating layer 30 and a reflective member 105 are not included. Thus, description of structures, functions, materials, effects, and the like that are similar to those of the first embodiment will be omitted.

In the semiconductor device according to the present embodiment, the lower electrode 2 may have light reflectivity. Such a configuration can reduce manufacturing time and costs of the semiconductor device and makes it possible to provide a low-priced semiconductor device.

### Third Embodiment

Next, one example of an organic light-emitting element usable in the semiconductor device according to the first or second embodiment will be described. A functional layer 4 of an organic light-emitting element according to the present embodiment may have, other than a light-emitting layer, a hole injection layer, a hole transport layer, an electron blocking layer, a hole/exciton blocking layer, an electron transport layer, an electron injection layer, and the like. The light-emitting layer may be a single layer and may be a laminated body including a plurality of layers. When the light-emitting layer includes a plurality of layers, an electric-charge generating layer may be provided between light-emitting layers. The electric-charge generating layer may be made of a compound having lower LUMO than the hole transport layer, and the LUMO of the electric-charge generating layer may be lower than HOMO of the hole transport layer. Here, molecular orbital energy of an organic compound layer may be molecular orbital energy of an organic compound contained in the organic compound layer at a largest weight ratio.

A substrate of the element substrate 1 may be made of, for example, quartz, glass, a silicon wafer, resin, metal, or the like. A switching element, such as a transistor, and a wire may be provided over the substrate, and an insulating layer may be provided over the switching element and the wire. When a silicon wafer is used as the substrate, an active layer of a transistor, a source region, and a drain region are formed inside the substrate. Such a configuration can be densely disposed.

A material of an interlayer insulating layer is not limited as long as a contact hole can be formed in the interlayer insulating layer so that a wire can be connected to a lower electrode and electrical insulation from wires not to be connected thereto can be ensured. For example, a resin of polyimide or the like, silicon oxide, silicon nitride, or the like is usable.

An electrode may be made of one type of a single material and may be made of a combination of materials of two types or more. An anode may be constituted by a single layer and may be constituted by a plurality of layers.

The insulating layer 3 serving as a pixel separation layer may be formed by, for example, a silicon nitride (SiN) film, a silicon oxynitride (SiON) film, or a silicon oxide (SiO) film that is formed by chemical vapor deposition (CVD).

A taper angle of an end portion of the insulating layer 3 and the film thickness of the pixel separation layer may be adjusted to an extent with which no gap is formed in the insulating layer 6 (protective layer) formed over the insulating layer 3. Since no gap is formed in the insulating layer 6 as the protective layer, defects generated in the insulating layer 6 can be reduced. Since defects generated in the protective layer are reduced, it is possible to reduce degradation in reliability, such as generation of dark spots and generation of electrical-continuity failures in an upper electrode.

By adjusting the taper angle of an end portion of the insulating layer 3, it is possible to effectively suppress electric charge leakage to adjacent pixels. It is found that the reduction can be sufficiently performed, as described above, when the taper angle is within a range of, for example, 60 degrees to 90 degrees. The film thickness of the insulating layer 3 may be 10 nm to 150 nm.

The functional layer 4 may have layers other than the electric-charge transport layer 44 and the light-emitting layer. Layers of the functional layer 4 may be each referred to as a hole injection layer, a hole transport layer, an electron blocking layer, a light-emitting layer, a hole blocking layer, an electron transport layer, or an electron injection layer depending on a function of each layer. The functional layer 4 is mainly made of an organic compound but may contain an inorganic atom and/or an inorganic compound. For example, the functional layer 4 may contain copper, lithium, magnesium, aluminum, iridium, platinum, molybdenum, zinc, and the like.

When the functional layer 4 has a plurality of light-emitting layers, the functional layer 4 may include an electric-charge generation portion between a first light-emitting layer 45 and a second light-emitting layer 46. The electric-charge generation portion may contain an organic compound having lowest unoccupied molecular orbital energy (LUMO) of −5.0 eV or less. The same applies to a case where an electric-charge generation portion is provided between the second light-emitting layer 46 and a third light-emitting layer.

The insulating layer 6 may be provided as a protective layer over the upper electrode. For example, a passivation film of silicon nitride or the like may be provided, as the insulating layer 6, over the upper electrode 5 to reduce infiltration of water and the like with respect to the functional layer 4. For example, a protective layer is formed by, after forming the upper electrode 5, transporting the upper electrode 5 to a different chamber while vacuum is maintained and forming a silicon nitride film having a thickness of 2 μm by CVD. The insulating layer 6 that is formed by ALD after film formation by CVD may be provided. The material of the film that is formed by ALD is not limited but may be silicon nitride, silicon oxide, aluminum oxide, or the like. A silicon nitride film may be further formed by CVD over the film formed by ALD. The film that is formed by ALD may have a smaller film thickness than the film that is formed by CVD. Specifically, the film thickness of the film that is formed by ALD may be 50% or less and, further, 10% or less.

The insulating layer 8 that mitigates irregularities of the upper surface of the insulating layer 6 and functions as a planarization layer may be disposed on the insulating layer 6. The insulating layer may be a low molecular or high molecular organic compound. The insulating layer 8 may be made of an inorganic material and may contain silicon oxide, silicon nitride, or the like. When the semiconductor device includes a color filter, the insulating layer 8 may be provided over and below the color filter, and constituent materials thereof may be the same or different. Specifically, examples of the constituent materials are a polyvinyl carbazole resin, a polycarbonate resin, a polyester resin, an ABS resin, an acrylic resin, a polyimide resin, a phenolic resin, an epoxy resin, a silicon resin, a urea resin, and the like.

The semiconductor device may include optical members including a microlens 9 and the like on the light emission side thereof. The microlens 9 can be made of an acrylic resin, an epoxy resin, or the like. Purposes of the microlens 9 may be an increase in the amount of light extracted from the light-emitting device and control of the direction of the extracted light. The microlens 9 may have a shape of a hemisphere. When the microlens 9 has a shape of a hemisphere, tangential lines in contact with the hemisphere include a tangential line parallel to an insulating layer, and a point of contact between the tangential line and the hemisphere is the vertex of the microlens 9.

The vertex of the microlens 9 can be similarly determined also in any sectional view. In other words, tangential lines in contact with a semicircle of the microlens 9 in a sectional view include a tangential line parallel to an insulating layer, and a point of contact between the tangential line and the semicircle is the vertex of the microlens.

The midpoint of the microlens 9 can also be defined. In a cross-section of the microlens 9, a line segment from a point at which a shape of an arc ends to a point at which a shape of another arc ends is imagined, and a midpoint of the line segment can be called the midpoint of the microlens 9. The cross-section in which the vertex and the midpoint are identified may be a cross-section perpendicular to an insulating layer.

The microlens 9 has a first surface having a protruding portion and a second surface opposite to the first surface. The second surface is disposed closer than the first surface to the functional layer. To obtain such a configuration, the microlens 9 is required to be formed over the light-emitting element 10. When the functional layer may be an organic layer, to avoid processes in which temperature is increased to a high temperature in a manufacturing step. When a configuration in which the second surface is disposed closer than the first surface to the functional layer is employed, all glass transition temperatures of organic compounds constituting the organic layer are 100 degrees or higher, or 130 degrees or higher.

A counter substrate may be provided over the insulating layer 8, a color filter 7, or the microlens 9. The counter substrate is provided at a position facing the above-described substrate and thus is called counter substrate. A constituent material of the counter substrate may be the same as the constituent material of the above-described substrate. The counter substrate may be a second substrate when the above-described substrate is defined as a first substrate.

The semiconductor device may include a pixel circuit that is connected to a light-emitting element. The pixel circuit may be of an active matrix type that controls light emission of each of a first light-emitting element and a second light-emitting element independently. The circuit of the active matrix type may use either voltage programming or current programming. A drive circuit includes the pixel circuit for each pixel. The pixel circuit may include a light-emitting element; a transistor that controls light emission luminance of the light-emitting element; a transistor that controls light emission timing; a capacitance that holds a gate voltage of the transistor that controls light emission luminance; and a transistor for connection to GND not via the light-emitting element.

The semiconductor device may have a display region and a peripheral region that is arranged at the periphery of the display region. A pixel circuit is provided in the display region, and a display control circuit is provided in the peripheral region. The mobility of a transistor that constitutes the pixel circuit may be less than the mobility of a transistor that constitutes the display control circuit.

The gradient of current-voltage characteristics of the transistor that constitutes the pixel circuit may be smaller than the gradient of current-voltage characteristics of the transistor that constitutes the display control circuit. The gradient of current-voltage characteristics can be measured by so-called Vg-Ig characteristics.

A transistor that constitutes the pixel circuit is a transistor that is connected to a light-emitting element, for example, a first light-emitting element.

The semiconductor device includes a plurality of pixels, as described in the above-described embodiments. The pixels include respective sub-pixels SP that emit light of colors different from each other. The sub-pixels SP may have respective emission colors of, for example, RGB.

In each pixel, a region, which is also called pixel opening, emits light. This region is the same as a light emission region 101, a light emission region 201, or a light emission region 301. In the semiconductor device according to at least any one of the first to third embodiments, a distance between sub-pixels (the centers of adjacent sub-pixels) is, for example, 6.4 μm or less.

Pixels can be arranged in a publicly known arrangement form in plan view. For example, pixels may be arranged in a stripe arrangement, a delta arrangement, a honeycomb arrangement, a pentile arrangement, or a bayer arrangement. Each sub-pixel may have any publicly known shape in plan view. Examples of the shape are quadrangular shapes, such as a rectangular shape and a rhombus shape, hexagonal shapes, and the like. Naturally, quadrangular shapes are not limited to accurate figures and include shapes that are proximate to quadrangular shapes. Shapes of sub-pixels and a pixel arrangement can be used in combination.

The semiconductor device described in any one of the aforementioned first to third embodiments can be used as a constituent member of a display device or the like. For example, the semiconductor device is applicable as a light-emitting device or the like including a color filter in a white light source.

A display device may be an image information processor that includes an image input portion, to which image information from an area CCD, a linear CCD, a memory card, or the like is input, and an information processing portion, which processes input information, and displays an input image on a display portion. The display portion can include the semiconductor device described in any one of the first to third embodiments.

A display portion of an imaging device or an inkjet printer may include the display device according to any one of the first to third embodiments. The display portion may have a touch panel function. The drive system of this touch panel function is not particularly limited and may be an infrared type, an electrostatic capacitive type, a resistive film type, or an electromagnetic induction type. The display device may be used in a display portion of a multifunctional printer.

Next, a device according to the present embodiment will be described with reference to the drawings.

FIG. 14 is a schematic sectional diagram illustrating an example of a semiconductor device that includes an organic light-emitting element and a transistor connected to the organic light-emitting element. The transistor is one example of an active element. The transistor is a thin-film transistor (TFT) in the example presented here. However, a MOSFET in which a semiconductor substrate is used is also usable. By using the MOSFET, transistors inside respective pixels can be disposed, in a smaller area, in an arrangement based on the aforementioned embodiments.

FIG. 14 illustrates one example of pixels that are components of the semiconductor device according to the present embodiment. Each pixel includes a sub-pixel SP. The sub-pixels are categorized into SPR, SPG, and SPB depending on light emission thereof. Emission colors may be distinguished based on wavelengths of light that is emitted from light-emitting layers, and light that is emitted from the sub-pixels may be further selectively transmitted or color-transformed by color filters or the like. In each sub-pixel SP, the semiconductor device includes the lower electrode 2 positioned over the element substrate 1; the insulating layer 3 that covers at least one end of the lower electrode 2; the functional layer 4 that covers the lower electrode 2 and the insulating layer 3; the upper electrode 5; and the insulating layer 6.

A transistor and a capacitor element may be disposed at a lower layer or an inside of the element substrate 1. The transistor and the lower electrode 2 may be electrically connected to each other through a contact hole (not illustrated) or the like.

The insulating layer 3 is also called a bank or a pixel separation film. The insulating layer 3 covers an end of the lower electrode 2 and is disposed so as to surround the lower electrode 2. A portion where the insulating layer 3 is not disposed is in contact with the functional layer 4 to serve as a light-emission region.

The functional layer 4 has an electric-charge transport layer 44 which functions as a hole transport layer, a first light-emitting layer 45, an electric-charge generating layer 42, and a second organic layer 43 including a second light-emitting layer 46.

The upper electrode 5 may be a transparent electrode or a semi-transparent electrode.

The insulating layer 6 reduces permeation of moisture through the functional layer 4. The insulating layer 6 is illustrated as a single layer but may be a plurality of layers. An inorganic compound layer or an organic compound layer may be present in each layer.

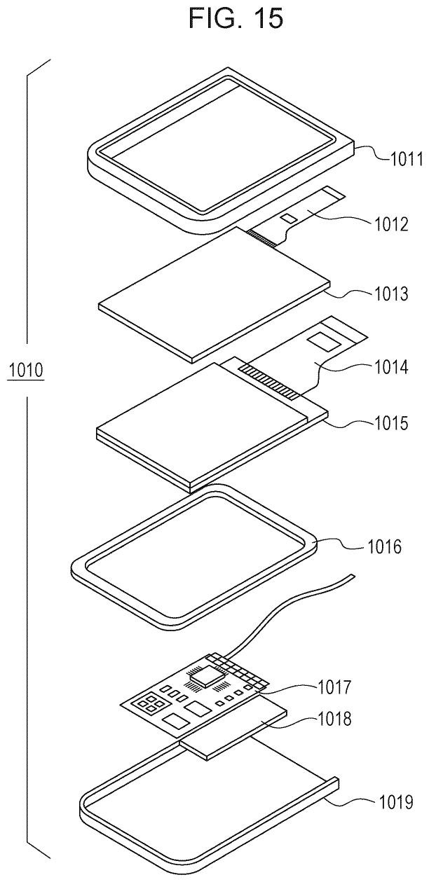

FIG. 15 is a schematic diagram illustrating an example of a display device as one example of the device. A display device 1010 includes, between an upper cover 1011 and a lower cover 1019, a touch panel 1013, a display panel 1015, a frame 1016, a circuit board 1017, and a battery 1018. Flexible printed circuits (FPCs) 1012 and 1014 are connected to the touch panel 1013 and the display panel 1015, respectively.

The display panel 1015 includes the semiconductor device according to at least any one of the first to third embodiments. A transistor is printed on the circuit board 1017. The battery 1018 may be not provided when the display device is not a mobile device and may be provided at a different position when the display device is a mobile device.

The display device according to the present embodiment may be used in a display portion of a mobile terminal. At that time, the display device may have both a display function and an operation function. Examples of the mobile terminal are a mobile telephone, such as a smartphone, a tablet, a head-mounted display (HMD), and the like.

The display device according to the present embodiment may be used in a display portion of an imaging device including an optical portion that includes a plurality of lenses and an imaging element that receives light that has passed through the optical portion. The imaging device may include the display portion that displays information acquired by the imaging element. The display portion may be a display portion that is exposed to the outside of the imaging device or a display portion that is disposed inside a finder. The imaging device may be a digital camera or a digital video camera.

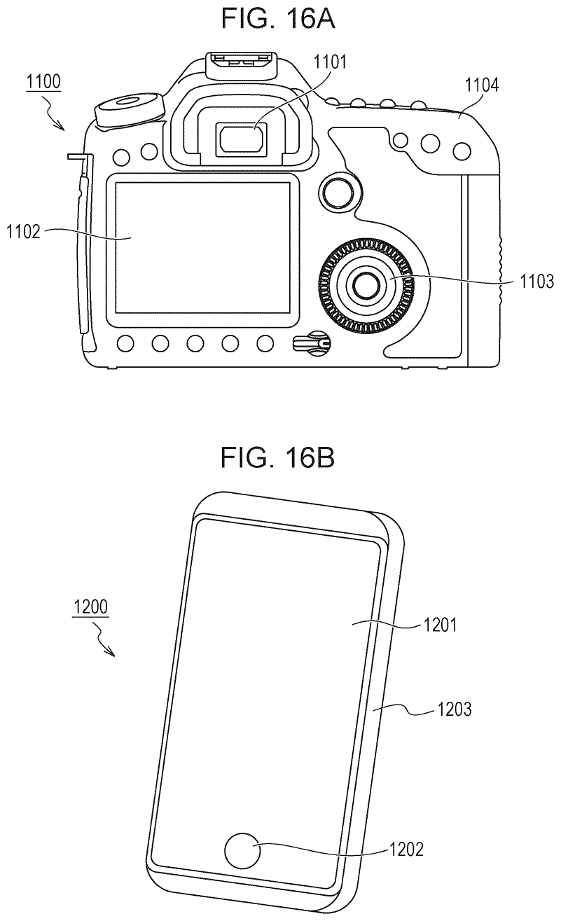

FIG. 16A is a schematic diagram illustrating, as an application example of the semiconductor device according to the present embodiment, one example of the imaging device. An imaging device 1100 may include a view finder 1101, a rear display 1102, an operation portion 1103, and a housing 1104. The view finder 1101 may include, as a display, the semiconductor device according to at least any one of the first to third embodiments. In that case, the organic light-emitting device may display not only imaged images but also environmental information, imaging instructions, and the like. The environmental information may include intensity of external light, directions of external light, moving speed of an object, possibility of an object being covered by an obstruct, and the like.

Information is displayed as soon as possible since suitable timing for imaging is a short amount of time. Accordingly, the semiconductor device according to any one of the first to third embodiments in which an organic light-emitting element may be used. This is because response speed of organic light-emitting elements is fast. Display devices in which organic light-emitting elements are used are required to perform display speedily. In this respect, the semiconductor device according to any one of the first to third embodiments can be used more suitably than liquid crystal display apparatuses.

The imaging device 1100 includes an optical portion (not illustrated). The optical portion includes a plurality of lenses and forms an image on an imaging element accommodated inside the housing 1104. The focal points of the plurality of lenses are adjustable by adjusting the relative positions thereof. This operation can also be performed automatically. The imaging device may be called a photoelectric conversion device. The photoelectric conversion device can have, as methods of imaging instead of successive imaging, a method in which differences are detected from previous images, a method in which images are cut out from constantly recorded images, and the like.

FIG. 16B is a schematic diagram illustrating one example of the electronic device according to the present embodiment. An electronic device 1200 includes a display portion 1201, an operation portion 1202, and a housing 1203. The housing 1203 may accommodate a circuit, a printed circuit board that includes the circuit, a battery, and a communication portion.

The display portion 1201 may include the semiconductor device according to at least any one of the first to third embodiments. The operation portion 1202 may be a button or a reactive portion of a touch panel type. The operation portion may be a biometric portion that recognizes a fingerprint to cancel locking. The electronic device that includes the communication portion can be called a communication device. The electronic device may further have a camera function by being provided with a lens and an imaging element. An image that is imaged by the camera function is displayed on the display portion. Examples of the electronic device are a smartphone, a notebook personal computer, and the like.

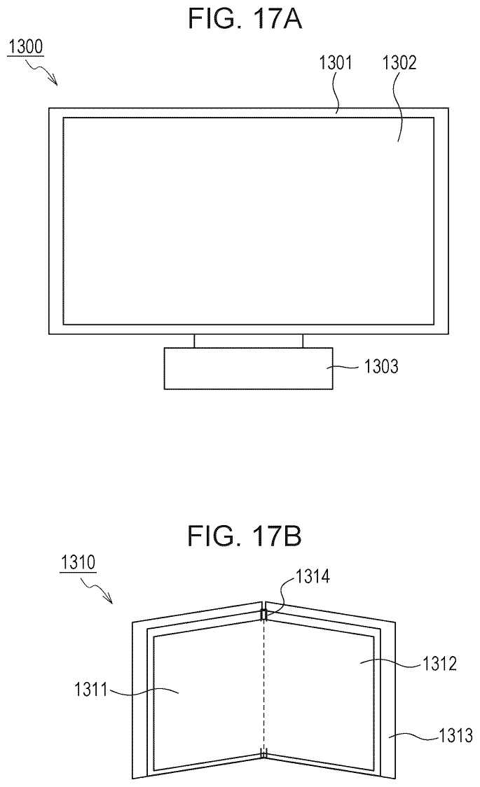

FIG. 17A is a schematic diagram illustrating one example of the display device according to the present embodiment. FIG. 17A illustrates a display device, such as a TV monitor or a PC monitor. A display device 1300 includes a frame 1301 and a display portion 1302 that is surrounded by the frame 1301. The light-emitting device according to at least any one of the first to third embodiments may be used in the display portion 1302.

The display device 1300 further includes a base 1303 that supports the frame 1301 and the display portion 1302. The base 1303 is not limited to be in the form in FIG. 17A. For example, the lower side of the frame 1301 may also serve as the base.

The frame 1301 and the display portion 1302 may be curved. The radiuses of curvatures thereof may be 5000 mm or more and 6000 mm or less.

FIG. 17B is a schematic diagram illustrating another example of the display device according to the present embodiment. A display device 1310 in FIG. 17B is configured to be foldable and is a so-called foldable display device. The display device 1310 includes a first display portion 1311, a second display portion 1312, a housing 1313, and an inflection point 1314. Each of the first display portion 1311 and the second display portion 1312 may include the semiconductor device according to at least any one of the first to third embodiments. The first display portion 1311 and the second display portion 1312 may be formed as a single display device without a joint. The first display portion 1311 and the second display portion 1312 can be divided at the inflection point. The first display portion 1311 and the second display portion 1312 may display images different from each other, and the first and second display portions display a single image.

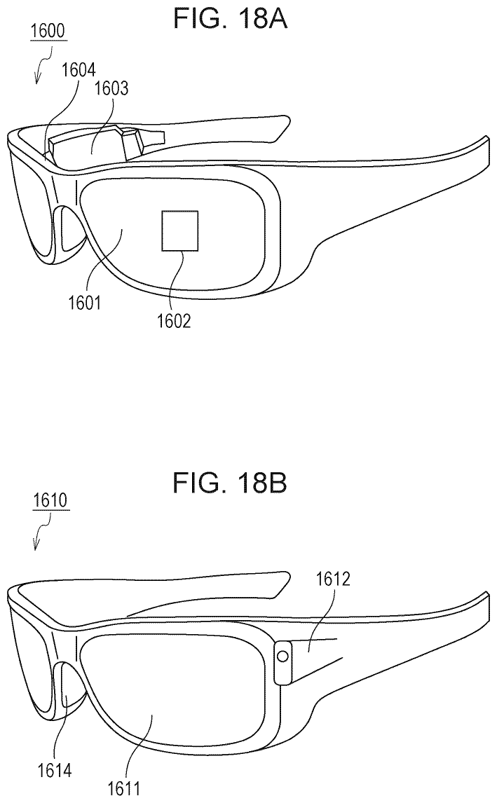

With reference to FIGS. 18A and 18B, application examples of a display device that includes the above-described semiconductor device according to any one of the first to third embodiments will be described. The display device is applicable to, for example, systems that are mountable as wearable devices, such as smart glasses, HMDs, and smart contact lenses. The imaging device and the display device used in such application examples can be an imaging device capable of photoelectrically converting visible light and a display device capable of emitting visible light, respectively.

FIG. 18A illustrates an eyewear 1600 (smart glasses) according to one application example. An imaging device 1602, such as a CMOS sensor or a SPAD, is provided on the front surface side of a lens 1601 of the eyewear 1600. In addition, a display device 1604 that includes the semiconductor device according to at least any one of the first to third embodiments described above is provided on the back surface side of the lens 1601.

The eyewear 1600 further includes a controller 1603. The controller 1603 functions as a power source that supplies electric power to the imaging device 1602 and the display device 1604. The controller 1603 also controls operations of the imaging device 1602 and the display device. An optical system for converging light at the imaging device 1602 is formed in the lens 1601.

FIG. 18B illustrates an eyewear 1610 (smart glasses) according to one application example. The eyewear 1610 includes a controller 1612. An imaging device corresponding to the imaging device 1602 and a display device 1614 corresponding to the display device 1604 are mounted on the controller 1612. An optical system for projection of light emitted by the display device 1614 inside the controller 1612 is formed at the lens 1611, and an image is projected on the lens 1611. The controller 1612 functions as a power source for supplying electric power to the imaging device and the display device 1614 and controls operations of the imaging device and the display device 1614.

The controller may include a gaze detection portion that detects a line of sight of a wearer. Infrared light may be used for gaze detection. An infrared-light emitting portion emits infrared light with respect to eyeballs of a user gazing at a displayed image. An imaging portion that includes a light-receiving element detects reflected light of the emitted infrared light reflected by the eyeballs, thereby obtaining an imaged image of the eyeballs. Image-quality degradation is reduced by including a reduction unit configured to reduce light that is emitted from the infrared-light emitting portion to a display portion in plan view.

From the imaged image of the eyeballs obtained through imaging of infrared light, a line of sight of the user with respect to the displayed image is detected. Any publicly known method is applicable for gaze detection using an imaged image of eyeballs. As one example, a gaze detection method based on a purkinje image generated by reflection of irradiation light on corneas is usable.

More specifically, a gaze detection process based on pupil center corneal reflection is performed. By using the pupil center corneal reflection, a gaze vector, which indicates a direction (rotation angle) of the eyeballs, is calculated on the basis of an image of pupils and a purkinje image included in the imaged image of the eyeballs, thereby detecting the line of sight of the user.

The eyewear 1610 according to an embodiment may include an imaging device that includes a light-receiving element and may control, on the basis of line-of-sight information of the user from the imaging device, an image displayed by the display device.

Specifically, on the basis of the line-of-sight information, a first display region that a user gazes at and a second display region other than the first display region are determined on the display device 1614. The first display region and the second display region may be determined by the controller of the eyewear 1610 and may be display regions that are determined by and received from an external controller. In the display region of the display device 1614, a display resolution of the first display region may be controlled to be higher than a display resolution of the second display region. In other words, the resolution of the second display region may be set to be lower than the resolution of the first display region.

The display region includes the first display region and the second display region that is different from the first display region, and a high-priority region is determined from the first display region and the second display region on the basis of the line-of-sight information. A first visual-field region and a second visual-field region may be determined by the controller of the display device, or a first visual-field region and a second visual-field region that are determined by an external controller may be received. The resolution of the high-priority region may be controlled to be higher than the resolution of regions other than the high-priority region. In other words, the resolution of regions having relatively low priority may be decreased.

AI may be used to determine the first display region and the high-priority region. AI may be a model that is configured to use, as teacher data, an image of eyeballs and an actual gaze direction of the eyeballs in the image and estimate, from the image of the eyeballs, an angle of a line of sight and a distance to a target object at which the line of sight is directed. An AI program may be included in the display device, in the imaging device, or in an external device. When an external device includes an AI program, the AI program is transmitted to the display device through communication.

When display is controlled on the basis of visual recognition detection, the eyewear 1610 is applicable to smart glasses further including an imaging device that images outside. The smart glasses can display, in real time, information on the outside that is imaged.

As described above, by applying the semiconductor device according to at least any one of the first to third embodiments to various devices according to the present embodiment, it is possible to downsize the devices or increase definition of the devices without increasing the size thereof. It is also possible to provide the devices in which variations at the time of manufacture are reduced.

The present disclosure includes, for example, the following components.

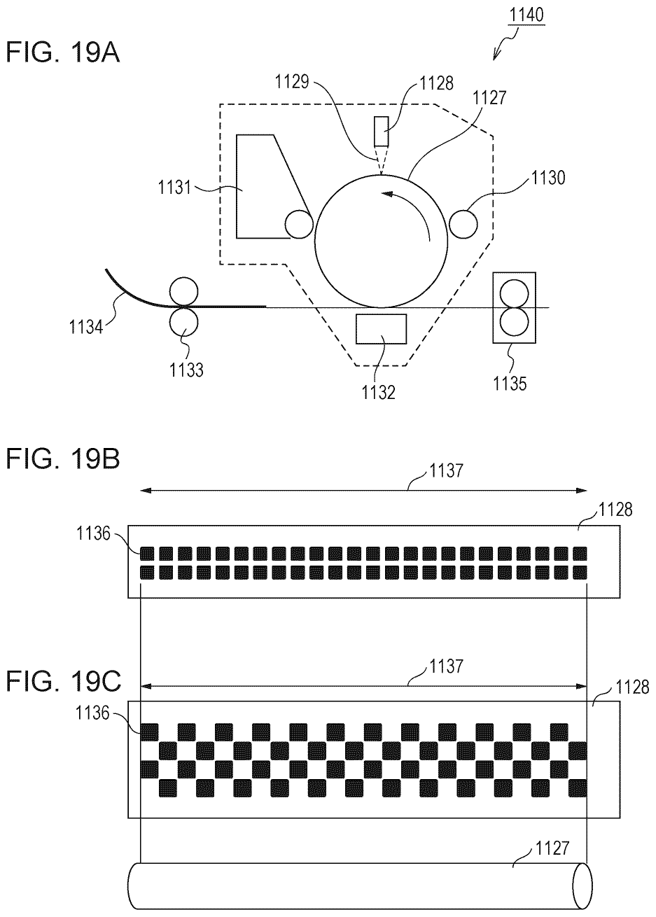

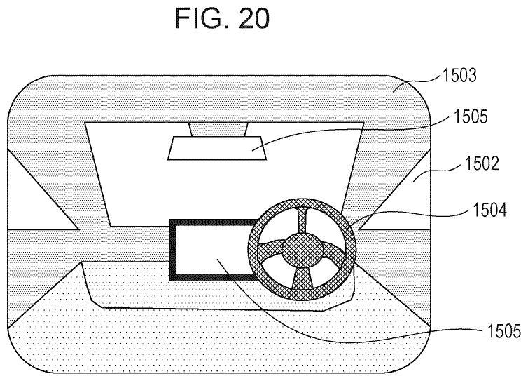

FIG. 19A and FIG. 19B each illustrate an image forming device according to the present embodiment. FIG. 19A is a schematic diagram of an image forming device 1140 according to the present embodiment. The image forming device includes a photoconductor, an exposure light source, a developing unit, a charging unit, a transferring unit, a transport roller, and a fixing unit.

An exposure light source 1128 emits light 1129 to form an electrostatic latent image on a surface of a photoconductor 1127. This exposure light source includes the semiconductor device according to the present disclosure. A developing unit 1131 has toner or the like. A charging unit 1130 electrically charges the photoconductor. A transferring unit 1132 transfers a developed image to a recording medium 1134. A transporting unit 1133 transports the recording medium 1134. The recording medium 1134 is, for example, a sheet of paper. A fixing unit 1135 fixes an image formed on a recording medium to the recording medium.

FIG. 19B and FIG. 19C are schematic diagrams each illustrating a state of the exposure light source 1128 in which a plurality of light-emitting portions 1136 are disposed on an elongated substrate. A direction 1137 is parallel to an axis of the photoconductor and indicates a line direction in which light-emitting portions each including the semiconductor device are arranged. The line direction is the same as a direction of an axis about which the photoconductor 1127 rotates. This direction can also be called the longitudinal direction of the photoconductor.

FIG. 19B illustrates a form in which the light-emitting portions are arranged in the longitudinal direction of the photoconductor. FIG. 19C illustrates a form, which differs from the form in FIG. 19B, in which light-emitting portions are arranged in each of a first line and a second line alternately in the line direction. The first line and the second line are arranged in positions that differ from each other in a row direction.

The first line includes a plurality of the light-emitting portions 1138 that are arranged to be spaced from each other. The second line includes light-emitting portions at positions corresponding to respective gaps between the light-emitting portions in the first line. In other words, a plurality of the light-emitting portions are arranged to be spaced from each other also in the row direction. As each of the light-emitting portions 1138, the semiconductor device according to at least one of the first to third embodiments is usable.

In other words, the arrangement in FIG. 19C is, for example, a state in which light-emitting portions are arranged in a lattice form or a state in which light-emitting portions are arranged in a staggered pattern or, in other words, a checkered pattern.

FIG. 20 is a schematic diagram of an automobile, which is one example of a movable body. An automobile 1500 includes a steering wheel 1504 that controls the moving direction of the movable body, a display 1505 that is mounted on a vehicle body 1503 to display a map, a position and a turning direction of the movable body, and the like. The display 1505 may include the organic light-emitting device according to at least one of the first to third embodiments.

Although an automobile has been described as an example here, the movable body according to the present embodiment is not limited to an automobile. The movable body according to the present embodiment includes one or both of a driving-force generator that generates a driving force, which is to be utilized mainly for movement of the movable body, and a rotor, which is to be utilized mainly for movement of the movable body. The driving-force generator can be an engine, a motor, or the like. The rotor can be a tire, a wheel, a screw of a marine vessel, a propeller of a flight vehicle, or the like. Specifically, the movable body may be a bicycle, an automobile, a train, a marine vessel, an aircraft, a drone, or the like.

The movable body may include a machine body and a lighting appliance provided on the machine body or a display provided on the machine body. The lighting appliance may emit light for indicating the position of the machine body. The lighting appliance may include the organic light-emitting element according to the present embodiment. The display also may include the organic light-emitting element according to the aforementioned embodiment.

It is possible to provide a technology that is advantageous for suppressing leakage current between light-emitting elements and leakage current between an upper electrode and an electric-charge generating layer and between an electric-charge generating layer and a lower electrode.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-208062, filed Nov. 29, 2024, which is hereby incorporated by reference herein in its entirety.

What is claimed is:

1. A semiconductor device comprising:
a lower electrode disposed over an element substrate;
an insulating layer disposed over the element substrate and covering an end of the lower electrode;
an organic layer disposed over the lower electrode and the insulating layer; and
an upper electrode disposed over the lower electrode and the insulating layer, the organic layer being interposed between the upper electrode and each of the lower electrode and the insulating layer,
wherein the organic layer includes a first light-emitting layer, a second light-emitting layer, and an electric-charge generating layer disposed between the first light-emitting layer and the second light-emitting layer, and
wherein, in a cross-section passing through the lower electrode, the insulating layer, and the organic layer:
an upper surface of the insulating layer has a groove,
the groove includes a bottom portion, a first steep slope portion, and a first gentle slope portion,
the first steep slope portion is inclined at an angle greater than 50 degrees with respect to a parallel surface parallel to a lower surface of the lower electrode,
the first gentle slope portion is disposed between the bottom portion and the first steep slope portion and is inclined at an angle less than or equal to 50 degrees with respect to the parallel surface, and
a length of the first steep slope portion in a first direction perpendicular to the parallel surface is less than a length from an upper surface of the lower electrode to a lower surface of the electric-charge generating layer in the first direction in a first region in which the lower electrode is in contact with the organic layer.

2. The semiconductor device according to claim 1, wherein:
in the cross-section, the groove includes a second steep slope portion at a position facing the first steep slope portion and a second gentle slope portion between the second steep slope portion and the bottom portion,
the second steep slope portion is inclined at an angle greater than 50 degrees with respect to the parallel surface, and
the second gentle slope portion is inclined at an angle less than or equal to 50 degrees with respect to the parallel surface.

3. The semiconductor device according to claim 1,
wherein, in the cross-section, a distance between upper end portions of the groove in a second direction parallel to the parallel surface is larger than twice the length from the upper surface of the lower electrode to the lower surface of the electric-charge generating layer in the first region in the first direction.

4. The semiconductor device according to claim 1,
wherein an angle between at least a part of the first gentle slope portion and the parallel surface is 18 degrees or more.

5. The semiconductor device according to claim 1,
wherein, in a cross-section passing through the lower electrode, the insulating layer, and the organic layer:
the insulating layer includes, in a second region between the first region and the groove, a third steep slope portion that is inclined at an angle greater than 50 degrees with respect to the parallel surface,
the first light-emitting layer is disposed between the lower electrode and the electric-charge generating layer, and
a length of the third steep slope portion in the first direction is less than a length from the lower electrode to the electric-charge generating layer in the first direction in the first region.

6. The semiconductor device according to claim 1,
wherein, in a cross-section of the lower electrode, the insulating layer, and the organic layer,
the insulating layer includes, in a second region between the first region and the groove, a third steep slope portion that is inclined at an angle greater than 50 degrees with respect to the parallel surface,
the first light-emitting layer is disposed between the lower electrode and the electric-charge generating layer, and
a length of the groove in the first direction is greater than a length of the third steep slope portion in the first direction.

7. The semiconductor device according to claim 1,
wherein, in a cross-section passing through the lower electrode, the insulating layer, and the organic layer:
the insulating layer includes, in a second region between the first region and the groove, a third steep slope portion that is inclined at an angle greater than 50 degrees with respect to the parallel surface, and
the third steep slope portion and the groove overlap the lower electrode when viewed in a plan view of the parallel surface.

8. A semiconductor device comprising:
a lower electrode disposed over an element substrate;
an insulating layer disposed over the element substrate and covering an end of the lower electrode;
an organic layer disposed over the lower electrode and the insulating layer; and
an upper electrode disposed over the lower electrode and the insulating layer, the organic layer being interposed between the upper electrode and each of the lower electrode and the insulating layer,
wherein the organic layer has a first light-emitting layer, a second light-emitting layer, and an electric-charge generating layer disposed between the first light-emitting layer and the second light-emitting layer,
wherein, in a cross-section passing through the lower electrode, the insulating layer, and the organic layer:
an upper surface of the insulating layer has a groove,
the groove includes a bottom portion and a first steep slope portion that is inclined at an angle greater than 50 degrees with respect to a parallel surface parallel to a lower surface of the lower electrode,
a length of the first steep slope portion in a first direction perpendicular to the parallel surface is less than a length from an upper surface of the lower electrode to a lower surface of the electric-charge generating layer in the first direction in a first region in which the lower electrode is in contact with the organic layer, and
a ratio of a length of the groove in the first direction relative to a distance between upper end portions of the groove in a second direction parallel to the parallel surface is 3.6 or less.

9. The semiconductor device according to claim 8, wherein:
in the cross-section, the groove includes a second steep slope portion at a position facing the first steep slope portion and a gentle slope portion between the second steep slope portion and the bottom portion,
the second steep slope portion is inclined at an angle greater than 50 degrees with respect to the parallel surface, and
the gentle slope portion is inclined at an angle less than or equal to 50 degrees with respect to the parallel surface.

10. The semiconductor device according to claim 8,
wherein, in the cross-section, the distance between the upper end portions of the groove in the second direction is larger than twice the length from the upper surface of the lower electrode to the lower surface of the electric-charge generating layer in the first direction in the first region.

11. The semiconductor device according to claim 9,
wherein an angle between at least a part of the gentle slope portion and the parallel surface is 18 degrees or more.

12. The semiconductor device according to claim 8,
wherein, in a cross-section passing through the lower electrode, the insulating layer, and the organic layer:
the insulating layer includes, in a second region between the first region and the groove, a third steep slope portion that is inclined at an angle greater than 50 degrees with respect to the parallel surface,
the first light-emitting layer is disposed between the lower electrode and the electric-charge generating layer, and
a length of the third steep slope portion in the first direction is less than a length from the lower electrode to the electric-charge generating layer in the first direction in the first region.

13. The semiconductor device according to claim 8,
wherein, in a cross-section passing through the lower electrode, the insulating layer, and the organic layer:
the insulating layer includes, in a second region between the first region and the groove, a third steep slope portion that is inclined at an angle greater than 50 degrees with respect to the parallel surface,
the first light-emitting layer is disposed between the lower electrode and the electric-charge generating layer, and
a length of the groove in the first direction is greater than a length of the third steep slope portion in the first direction.

14. The semiconductor device according to claim 8,
wherein, in a cross-section passing through the lower electrode, the insulating layer, and the organic layer:
the insulating layer includes, in a second region between the first region and the groove, a third steep slope portion that is inclined at an angle greater than 50 degrees with respect to the parallel surface, and
the third steep slope portion and the groove overlap the lower electrode when viewed in a plan view of the parallel surface.

15. A display device comprising:
the semiconductor device according to claim 8; and
a transistor that is connected to the lower electrode of the semiconductor device.

16. A photoelectric conversion device comprising:
an optical portion that includes a plurality of lenses;
an imaging element that receives light that has passed through the optical portion; and
a display portion that displays an image that is imaged by the imaging element,
wherein the display portion includes the semiconductor device according to claim 8.

17. An electronic device comprising:
a display portion that includes the semiconductor device according to claim 8;
a housing that is provided with the display portion; and
a communication portion of the housing, configured to communicate with at least one external device.

18. Eyewear comprising:
a lens on which an imaging device and a display portion are disposed; and
a controller,
wherein the light-emitting device according to claim 8 is disposed at the display portion, and
wherein the controller is configured to control operations of the imaging device and the display portion.

19. An image forming device comprising:
an exposure light source that includes the semiconductor device according to claim 8; and
a photoconductor configured to be irradiated with light from the exposure light source.

20. A movable body comprising:
a vehicle body; and
a display portion mounted on the vehicle body,
wherein the display portion includes the semiconductor device according to claim 8.
